(19) United States
(12) Patent Application Publication
(10) Pub. No.: US 2025/0149524 A1
(43) Pub. Date: May 8, 2025

(54) PACKAGE STRUCTURE INCLUDING A REDISTRIBUTION LAYER (RDL) STRUCTURE WITH A RECESSED PORTION AND METHODS OF FORMING THE SAME

(71) Applicant: Taiwan Semiconductor Manufacturing Company Limited, Hsinchu (TW)

(72) Inventors: Chun-Sheng Fan, New Taipei City (TW); Ta-Hsuan Lin, Hsinchu City (TW); Hua-Wei Tseng, New Taipei City (TW); Wei-Cheng Wu, Hsinchu City (TW)

(21) Appl. No.: 18/501,062

(22) Filed: Nov. 3, 2023

(51) Int. Cl. H01L 25/18; H01L 21/56; H01L 23/00; H01L 23/31; H01L 25/00; H01L 25/065; H10B 80/00

(52) U.S. Cl. CPC H01L 25/18; H01L 21/568; H01L 23/3128; H01L 24/16; H01L 24/19; H01L 24/20; H01L 24/26; H01L 24/29; H01L 24/32; H01L 24/73; H01L 25/50; H01L 24/48; H01L 25/0657; H01L 2224/16227; H01L 2224/19; H01L 2224/214; H01L 2224/215; H01L 2224/26175; H01L 2224/2929; H01L 2224/29386; H01L 2224/32225; H01L 2224/48091; H01L 2224/48227; H01L 2224/73204; H01L 2225/0651; H01L 2225/06568; H01L 2924/01013; H01L 2924/01022; H01L 2924/01028; H01L 2924/01029; H01L 2924/05442; H01L 2924/0665; H10B 80/00

(57) ABSTRACT

A package structure includes a frontside redistribution layer (RDL) structure with a recessed portion, a lower encapsulation layer on the frontside RDL structure and a plurality of through vias connected to the frontside RDL structure to an upper package, a first semiconductor die on the frontside RDL structure and in the lower encapsulation layer, and an integrated passive device (IPD) connected to the frontside RDL structure in the recessed portion that connects to the first semiconductor die. A method of forming a package structure includes forming a molded portion with a lower encapsulation layer, a plurality of through vias in the lower encapsulation layer and a first semiconductor die in the lower encapsulation layer, forming a RDL structure with a recessed portion on the molded portion, the plurality of through vias connect the frontside RDL structure to an upper package, and attaching an IPD in the recessed portion.

### BACKGROUND

A package structure may include an integrated passive device (IPD). The IPD is an electronic device that may include one or more passive components such as resistors, capacitors and inductors. The IPD may be designed to provide important passive functionalities in an electronic circuit while occupying a small footprint, reducing parasitic effects, and improving overall performance. The IPD may commonly be used in various semiconductor packages and integrated circuits to simplify design, save space, and enhance circuit performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to various embodiments.

FIG. 1B is a bottom-up plan view of the board-side surface of a frontside RDL structure in the package structure according to one or more embodiments.

FIG. 1C is a detailed vertical cross-sectional view of a portion of the frontside RDL structure according to one or more embodiments.

FIG. 1D is a detailed vertical cross-sectional view of the recessed portion in the frontside RDL structure according to one or more embodiments.

FIG. 2A is a vertical cross-sectional view of an intermediate structure including a seed layer on an adhesive layer according to one or more embodiments.

FIG. 2B is a vertical cross-sectional view of an intermediate structure including a photoresist layer according to one or more embodiments.

FIG. 2C is a vertical cross-sectional view of an intermediate structure including the through vias according to one or more embodiments.

FIG. 2D is a vertical cross-sectional view of an intermediate structure including the through vias according to one or more embodiments.

FIG. 2E is a vertical cross-sectional view of an intermediate structure including the first semiconductor die according to one or more embodiments.

FIG. 2F is a vertical cross-sectional view of an intermediate structure including the lower encapsulation layer according to one or more embodiments.

FIG. 2G is a vertical cross-sectional view of an intermediate structure including the lower encapsulation layer after performing the planarization process, according to one or more embodiments.

FIG. 2H is a vertical cross-sectional view of an intermediate structure including the frontside RDL structure, according to one or more embodiments.

FIG. 2I is a vertical cross-sectional view of an intermediate structure including the UBM layer, according to one or more embodiments.

FIG. 2J is a vertical cross-sectional view of an intermediate structure including the IPD, according to one or more embodiments.

FIG. 2K is a vertical cross-sectional view of an intermediate structure including the solder balls, according to one or more embodiments.

FIG. 3 is a flow chart illustrating a method of forming a package structure, according to one or more embodiments.

FIG. 4 is a vertical cross-sectional view of a semiconductor device including an upper package on the package structure according to one or more embodiments.

FIG. 5 is a vertical cross-sectional view of a semiconductor package including the semiconductor device on a package substrate according to one or more embodiments.

FIG. 6 is a vertical cross-sectional view of a semiconductor device according to one or more embodiments.

FIG. 7 is a detailed vertical cross-sectional view of a first alternative design of the frontside RDL structure according to one or more embodiments.

FIG. 8 is a detailed vertical cross-sectional view of a second alternative design of the frontside RDL structure according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

IPDs may be used in semiconductor packages for many different purposes. For instance, by integrating multiple passive components into a single package, IPDs may minimize valuable board space and reduce the overall size of electronic devices. This is particularly beneficial in modern electronic devices in which size constraints are critical, such as for smartphones, wearables, and Internet of Things (IoT) devices.

IPDs may include capacitors and inductors that provide for filtering and signal conditioning. IPDs may also be used to suppress noise, eliminate unwanted frequencies, and shape signal waveforms in various applications, including wireless communication devices and radio frequency (RF) circuits. IPDs may also be used in RF and wireless communication applications to create impedance matching networks. Such impedance matching networks may help to ensure that the input and output impedances of a circuit match to optimize power transfer and signal integrity.

IPDs may also be used for direct current (DC) biasing and alternating current (AC) coupling in various circuits. IPDs may combine DC-blocking capacitors and DC-bias resistors into a single package, thereby reducing the number of discrete components needed and simplifying the circuit layout. IPDs may integrate resistors and capacitors used in voltage divider networks for power distribution, voltage sensing, and level shifting in power management circuits. IPDs may also be used in timing circuits and oscillators to create stable clock signals and timing references, in microelectromechanical systems (MEMS) and sensor applications for calibration, signal conditioning, and sensor element interfacing, and in advanced semiconductor packaging to enhance signal integrity, minimize parasitic effects and reduce the need for external components.

Usually, package structures may attach the IPD to a board-side surface of a redistribution layer (RDL) structure. The IPD may, in some instances, be electrically coupled to the second RDL layer (RDL2) which may be redundant as ground dummy mesh. The IPD may be formed adjacent to the solder balls of a ball grid array (BGA) on the board-side surface of the RDL structure. The solder balls may have a height (e.g., distance from the board-side surface) sufficient to provide clearance between the IPD and the package substrate (e.g., board) to which the package structure is mounted.

At least one embodiment disclosed herein may include a package structure with an IPD attached to the RDL structure in a recessed portion of the RDL structure. In at least one embodiment disclosed herein, the IPD may be at least partially formed or attached within the recessed portion. The IPD may include, for example, a zero-inductance IPD (ZLIPD). The package structure may include, for example, a package-on-package structure. In at least one embodiment, the package structure may include an application processor (AP) device.

By attaching the IPD to the RDL structure in the recessed portion, the package structure may reduce a height of the solder balls of the BGA. This may allow an embodiment package structure to have a thicker semiconductor die as compared to other package structures.

Further, an IPD underfill layer may be formed in the recessed portion and around at least a portion of the IPD. Attaching the IPD in the recessed portion may reduce an underfill material spreading distance along the board-side surface of the RDL structure. Therefore, attaching the IPD in the recessed portion may help to reduce a size of an underfill keep-out zone (KOZ) compared to other package structures. This may allow ball grid array (BGA) input/output (I/O) solder balls to be formed closer to the IPD, and thereby allow for an increase in a ball grid array (BGA) input/output (I/O) count.

In at least one embodiment, a height of the IPD may be reduced to 79 μm or less which may be at least 15 μm less than a height of the IPD (e.g., 94 μm) in a conventional package structure. In at least one embodiment, a height of the solder balls may be reduced to 111 μm or less which may be at least 15 μm less than a height of the solder balls (e.g., 126 μm) in the conventional package structure.

In at least one embodiment, the package structure may include an underbump metallization (UBM) dam structure (e.g., metal dam structure) on the board-side surface of the RDL structure. The UBM dam structure may help to contain and/or impede a spreading of the IPD underfill layer along the board-side surface of the RDL structure. In at least one embodiment, the package structure may also include a barrier ring (e.g., RDL3 barrier ring) in the recessed portion. The barrier ring may be used to contain and/or impede the spreading of the IPD underfill layer along the bottom surface of the recessed portion. In at least one embodiment, the barrier ring may be omitted. The UBM dam structure may be included in both cases—where RDL3 barrier ring is included and where the RDL3 barrier ring is not included. In both cases, a size of the underfill KOZ may be reduced and the BGA I/O count may be increased.

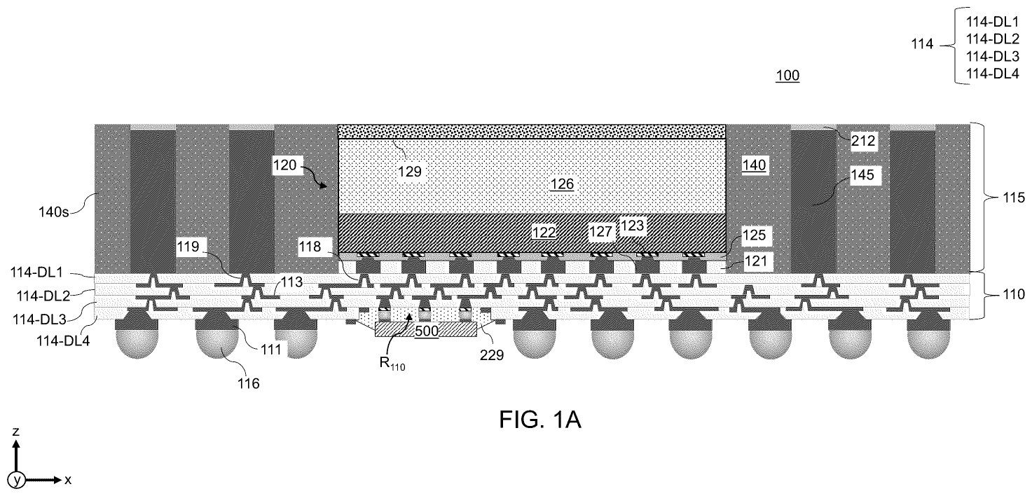

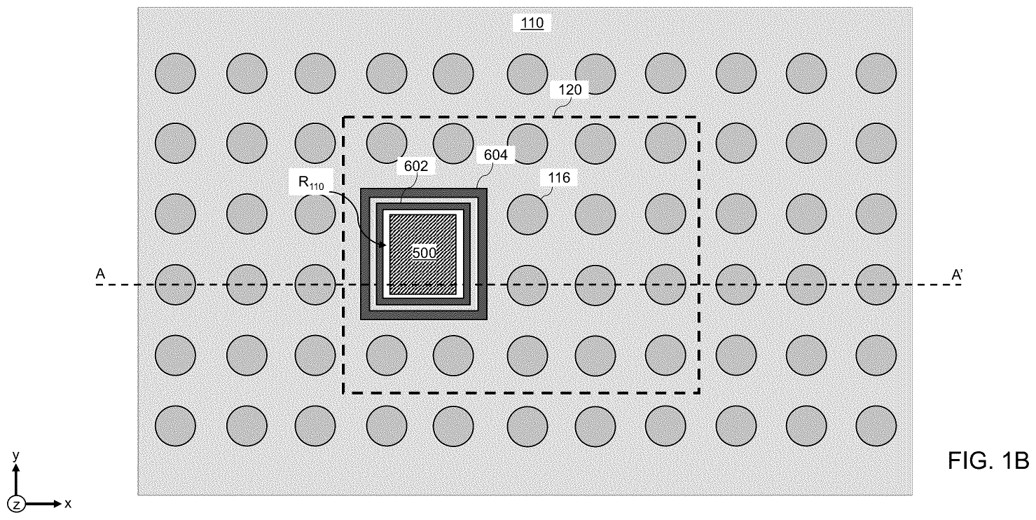

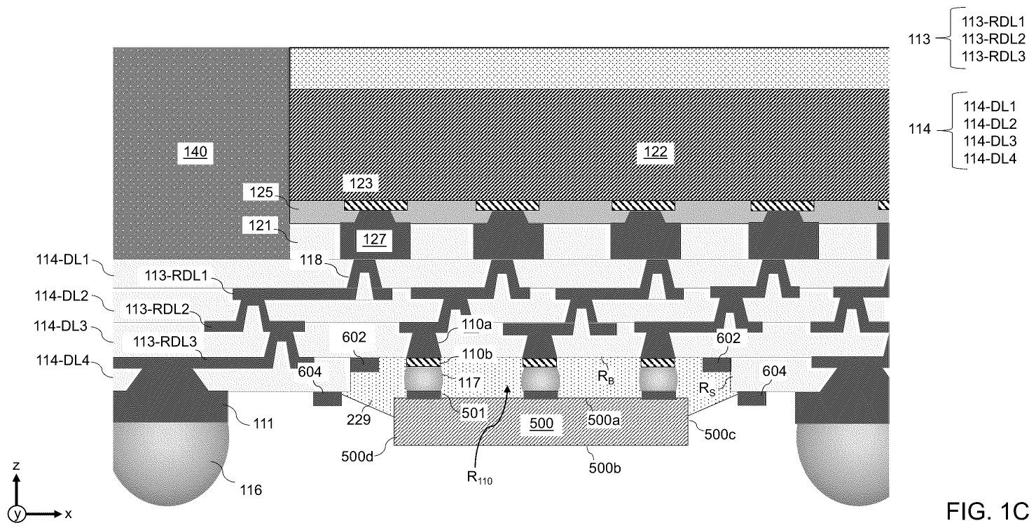

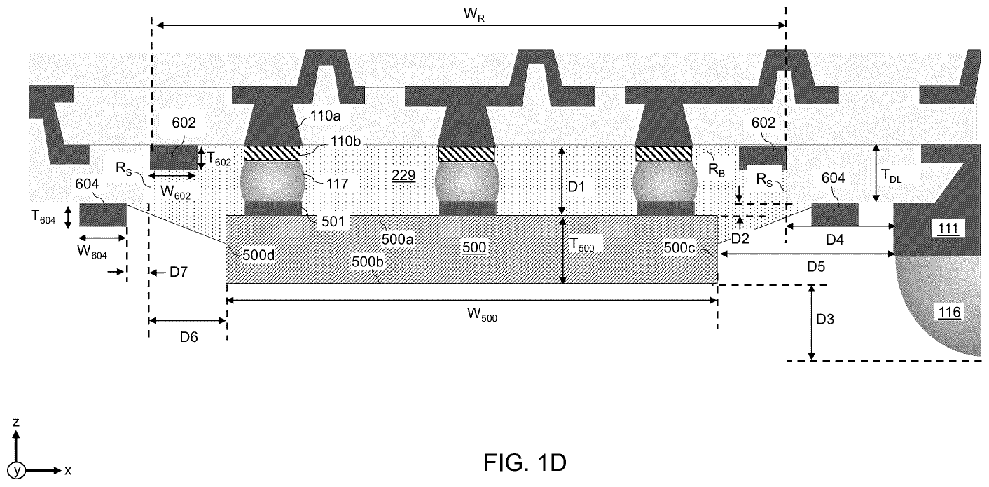

FIG. 1A is a vertical cross-sectional view of a package structure 100 according to various embodiments. FIG. 1B is a bottom-up plan view of the board-side surface of a frontside RDL structure 110 in the package structure 100 according to one or more embodiments. FIG. 1A is a cross-sectional view along the lines A-A′ in FIG. 1B. FIG. 1C is a detailed vertical cross-sectional view of a portion of the frontside RDL structure 110 according to one or more embodiments. FIG. 1D is a detailed vertical cross-sectional view of the recessed portion R₁₁₀ in the frontside RDL structure 110 according to one or more embodiments.

It should be noted that the embodiments are not limited to any particular package structure configuration or “package-on-package” configuration. It should also be noted that the terms “proximal” and “distal” may be used at times to describe elements of the package structure 100. These terms are used with reference to a central portion of the package structure 100 in the z-direction (e.g., vertical direction). Thus, for example, a “proximal” side of a redistribution layer may refer to a side of the redistribution layer that is nearest the central portion in the z-direction, and a “distal” side of the redistribution layer may refer to a side of the redistribution layer that is farthest away from the central portion in the z-direction.

As illustrated in FIG. 1A, the package structure 100 may include a frontside RDL structure 110 and a molded portion 115 on the frontside RDL structure 110. The molded portion 115 may include a first semiconductor die 120 attached to the frontside RDL structure 110. The frontside RDL structure 110 may include a recessed portion R₁₁₀. An integrated passive device (IPD) 500 may be attached to the frontside RDL structure 110 in the recessed portion R₁₁₀.

In at least one embodiment, the frontside RDL structure 110 may include a plurality of dielectric layers 114 and a plurality of redistribution layers 113 stacked alternately. The number of the dielectric layers 114 and the number of redistribution layers 113 in the frontside RDL structure 110 are not limited in any way by the disclosure. While FIG. 1A depicts four (4) dielectric layers 114 and four (4) redistribution layers 113, a greater or fewer number of the dielectric layers and redistribution layers may be used.

In at least one embodiment, the dielectric layers 114 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 113 may include conductive materials. The conductive materials may include metal such as copper, aluminum, nickel, titanium, a combination thereof or other suitable metals. The redistribution layers 113 may include metallic connection structures (e.g., metallic structures that provide electrical connection between nodes in the frontside RDL structure 110).

The redistribution layers 113 may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 113 may include copper, nickel, or copper and nickel. Other suitable metallic fill materials are within the contemplated scope of disclosure. The thickness of the metallic fill material that is deposited for each of the redistribution layers 113 may be in a range from 2 microns to 40 microns, such as from 4 microns to 10 microns, although lesser or greater thicknesses may also be used.

In at least one embodiment, the redistribution layers 113 may include a plurality of traces (lines) and a plurality of vias connecting the plurality traces to each other. The traces may be respectively located on the dielectric layers 114, and may extend in the x-direction (e.g., first horizontal direction) and y-direction (e.g., second horizontal direction) on the top surface of the dielectric layers 114.

The dielectric layers 114 in the frontside RDL structure 110 may include a proximal dielectric layer 114-DL1, a distal dielectric layer 114-DL4 and intermediate dielectric layers 114-DL2 and 114-DL3 between the proximal dielectric layer 114-DL1 and distal dielectric layer 114-DL4. The proximal dielectric layer 114-DL1 may include one or more vias 118 that may serve as RDL bonding pads for connecting the first semiconductor die 120 in the molded portion 115 to the frontside RDL structure 110. The proximal dielectric layer 114-DL1 may also include one or more vias 119 that may serve as frontside bonding pads for connecting one or more through vias (TVs) 145 in the molded portion 115 to the frontside RDL structure 110. The vias 119 may have a size (e.g., diameter, width in the x-direction, etc.) that is greater than a size of the vias 118. The vias 118 and vias 119 may be formed concurrently with the redistribution layers 113, and may include a metal such as copper, aluminum, nickel, titanium, a combination thereof or other suitable metals.

The distal dielectric layer 114-DL4 may include an under-bump metallurgy (UBM) layer 111. The UBM layer 111 may include a metal such as copper, aluminum, nickel, titanium, a combination thereof or other suitable metals. A portion of the UBM layer 111 may be disposed on an underside of the distal dielectric layer 114-DL4 and serve as a joint pad. A ball grid array (BGA) including a plurality of solder balls 116 (e.g., ball grid array (BGA) input/output (I/O) solder balls) may be located on the board-side surface of the distal dielectric layer 114-DL4. The BGA may be used to mount the package structure 100 onto a substrate such as a package substrate or printed circuit board (PCB).

The solder balls 116 of the BGA may be disposed on the UBM layers 111, respectively. The solder balls 116 may include a standard solder material (e.g., SAC304 or SAC405). The solder material may include a lead-free solder material. The solder material may include tin and one or more other elements such as silver, indium, antimony, bismuth, zinc, etc. Other suitable solder materials are within the contemplated scope of disclosure. The UBM layer 111 may alternatively include a microbump or metal pillar (e.g., copper pillar).

The recessed portion R₁₁₀ may be located in the distal dielectric layer 114-DL4. In at least one embodiment, at least a portion of the recessed portion R₁₁₀ may be located beneath the first semiconductor die 120 in the z-direction. The recessed portion R₁₁₀ may be located adjacent the solder balls 116 in the BGA. The IPD 500 may be centrally located in the recessed portion R₁₁₀. The IPD 500 may be electrically coupled to the first semiconductor die 120 through the redistribution layers 113 in the frontside RDL structure 110. The IPD 500 may include one or more electronic components such as resistors, capacitors, inductors, coils, chokes, microstriplines, impedance matching elements, baluns, etc.

An IPD underfill layer 229 may be formed in the recessed portion R₁₁₀ and around at least a portion of the IPD 500. The IPD underfill layer 229 may help to fix the IPD 500 to the frontside RDL structure 110. The IPD underfill layer 229 may have a low viscosity (e.g., less than about 5,000 cP at 10 rpm), and may be formed of an epoxy-based polymeric material. In at least one embodiment, the IPD underfill layer 229 may include a capillary underfill including a mixture of epoxy and silica. In at least one embodiment, the IPD underfill layer 229 may include a low-viscosity suspension of silica in prepolymer.

By attaching the IPD 500 to the frontside RDL structure 110 in the recessed portion R₁₁₀, as opposed to a non-recessed portion of the distal dielectric layer 114-DL4, the overall package structure 100 may reduce a height of the solder balls 116 of the BGA, as a thicker UBM layer and/or solder ball height would be used to provide the clearance for the IPD 500. The attachment of the IPD 500 within the recessed portion R₁₁₀ may allow the first semiconductor die 120 to have a greater thickness compared to semiconductor dies in other package structures.

In addition, attaching the IPD 500 in the recessed portion Rio may reduce an underfill material spreading distance along the board-side surface of the frontside RDL structure 110. Therefore, attaching the IPD 500 in the recessed portion R₁₁₀ may help to reduce a size of an underfill keep-out zone (KOZ) as compared to other package structures. This may allow the solder balls 116 to be formed closer to the IPD 500, and thereby allow for an increase in a ball grid array (BGA) input/output (I/O) count.

The molded portion 115 may be formed on the proximal dielectric layer 114-DL1 of the frontside RDL structure 110. The molded portion 115 may have a size and shape substantially the same as the size and shape of the frontside RDL structure 110. The molded portion 115 may include the first semiconductor die 120 attached to (e.g., mounted on) the proximal dielectric layer 114-DL1 of the frontside RDL structure 110. The first semiconductor die 120 may include, for example, a semiconductor chip or chiplet for a high performance computing (HPC) application, an artificial intelligence (AI) application, and a 5G cellular network application. In at least one embodiment, the first semiconductor die 120 may include a logic die (e.g., mobile application processor, microcontroller, etc.), or a memory die (e.g., dynamic random access memory (DRAM) die, a Wide I/O die, a M-RAM die, a R-RAM die, a NAND die, static random access memory (SRAM), etc.). In at least one embodiment, the first semiconductor die 120 may include a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

The first semiconductor die 120 may include, for example, an active region 122 on a frontside of the first semiconductor die 120, and a semiconductor layer 126 (e.g., bulk silicon region) on the active region 122. The active region 122 may include a front end of line (FEOL) region including electronic circuitry including various electronic devices (e.g., transistors, resistors, etc.). In particular, the FEOL region may include one or more logic circuits including logic devices (e.g., logic gates) and/or one or more memory circuits including memory devices (e.g., volatile memory (VM) devices and/or non-volatile memory (NVM) devices).

The active region 122 may also include a back end of line (BEOL) region on FEOL region. The BEOL region may include interlayer dielectric having a plurality of dielectric layers. The dielectric layers may include, for example, SiO₂, a dielectric polymer or other suitable dielectric material. The interlayer dielectric may include one or more metal interconnect structures formed therein. The metal interconnect structures may include metal traces and metal vias formed in the dielectric layers and provide an electrical connection to the electronic circuitry in the FEOL region.

The first semiconductor die 120 may also include one or more semiconductor die contact pads 123 on a surface of the active region 122. The semiconductor die contact pads 123 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The first semiconductor die 120 may also include a semiconductor die passivation layer 125 on the surface of the semiconductor die active region 122. In particular, the semiconductor die passivation layer 125 may at least partially cover the semiconductor die contact pads 123. The semiconductor die passivation layer 125 may include silicon oxide, silicon nitride, low-k dielectric materials such as carbon-doped oxides, extremely low-k dielectric materials such as porous carbon doped silicon dioxide, a combination thereof or other suitable material. A surface of the semiconductor die contact pads 123 may be exposed through openings in the passivation layer 125.

The first semiconductor die 120 may also include a dielectric layer 121 on the semiconductor die passivation layer 125. The dielectric layer 121 may include a dielectric polymer, silicon oxide, or other suitable dielectric materials. Semiconductor die bonding pads 127 may be formed in the dielectric layer 121 and contact the exposed surface of the semiconductor die contact pads 123 through the openings in the passivation layer 125. The semiconductor die bonding pads 127 may have one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. The first semiconductor die 120 may be connected to the frontside RDL structure 110 by connecting the semiconductor die bonding pads 127 to the vias 118 (e.g., RDL bonding pads) in the proximal dielectric layer 114-DL1.

The first semiconductor die 120 may also include a die attach film 129 (DAF) on the backside of the first semiconductor die 120. The DAF 129 may include, for example, a thermosetting polymer material that can be cured or hardened during the assembly process to form an adhesive. The DAF 129 may include, for example, an epoxy resin, a polyimide, a silicon-based material or an acrylate-based material.

As alternative to the DAF 129, the first semiconductor die may include a backside metal film on the backside of the first semiconductor die 120. The backside metal film may be formed on a surface of the semiconductor layer 126. The backside metal film may have a good adhesion to a semiconductor material (e.g., silicon) in the semiconductor layer 126. The backside metal film may include a high thermal conductivity (e.g., k>20 W/m*k) metal film. The backside metal film (e.g., high thermal conductivity backside metal film) may include, for example, a sintered metal film.

The molded portion 115 may also include one or more of the through vias (TVs) 145 adjacent to the first semiconductor die 120 on the frontside RDL structure 110. The through vias 145 may be configured to electrically couple the frontside RDL structure 110 to an upper package. The package structure 100 may therefore accommodate an integrated fan-out structure including the upper package. In particular, the package structure 100 may serve as a lower package of a “package-on-package” structure that includes the upper package mounted on the lower package.

The through vias 145 may be connected to the vias 119 (e.g., RDL bonding pads) in the proximal dielectric layer 114-DL1. The through vias 145 may have a columnar or cylindrical shape (e.g., circular cylinder shape). Other horizontal cross-sectional shapes may be used for the through vias 145 (e.g., oval, square, rectangular, etc.). The through vias 145 may have a diameter (e.g., width) in the x-direction that is greater than a width of the vias 119. The through vias 145 may include a seed layer 212 at an end of the through vias 145. The seed layer 212 may include, for example, copper or one or more other suitable metals. The seed layer 212 may have a height in the z-direction that is substantially the same as a height of the DAF 129 of the first semiconductor die 120. That is, a surface of the seed layer 212 may be substantially coplanar with a surface of the DAF 129. The through vias 145 may have one or more layers and may include metals, metal alloys, and/or other metal-containing compounds (e.g., Cu, Al, Mo, Co, Ru, W, TiN, TaN, WN, etc.). Other suitable metal materials for the through vias 145 are within the contemplated scope of disclosure.

The molded portion 115 may also include a lower encapsulation layer 140 on the frontside RDL structure 110. The lower encapsulation layer 140 may laterally (e.g., in the x-direction and y-direction) encapsulate the first semiconductor die 120 and the through vias 145. In at least one embodiment, the dielectric layer 121 may be omitted in which case the lower encapsulation layer 140 may also be located on and around the semiconductor die bonding pads 127 between the first semiconductor die 120 and the frontside RDL structure 110. A surface of the lower encapsulation layer 140 may be substantially coplanar with a surface of the seed layer 212 and a surface of the DAF 129. In some embodiments, the lower encapsulation layer 140 may include a molding compound, a molding underfill, a resin (such as an epoxy resin), or a combination thereof, or other suitable encapsulant materials.

Referring to FIG. 1B, the frontside RDL structure 110 may have a square shape or rectangular shape in the x-y plane. Other shapes of the frontside RDL structure 110 are within the contemplated scope of disclosure. Dashed lines are used in FIG. 1B to indicate a location of the first semiconductor die 120 with respect to the frontside RDL structure 110. The first semiconductor die 120 may have a shape in the x-y plane substantially similar to a shape of the frontside RDL structure 110. The first semiconductor die 120 may be located in a central region of the frontside RDL structure 110.

As illustrated in FIG. 1B, the recessed portion R₁₁₀ may have a square shape or rectangular shape. In at least one embodiment, the recessed portion R₁₁₀ may have a shape substantially similar to a shape of the frontside RDL structure 110. The IPD 500 may be centrally located (e.g., in the x-direction and/or in the y-direction) in the recessed portion R₁₁₀. The IPD 500 may have a shape substantially similar to a shape of the recessed portion R₁₁₀. The solder balls 116 of the BGA may be formed around a periphery of the recessed portion R₁₁₀.

A barrier ring 602 (e.g., RDL3 barrier ring) may be located in the recessed portion R₁₁₀. The barrier ring 602 may have a frame shape that is substantially similar to a shape of the recessed portion R₁₁₀. The barrier ring 602 may be formed adjacent the wall of the recessed portion R₁₁₀ around an outer periphery of the recessed portion R₁₁₀. In at least one embodiment, the barrier ring 602 may be located inside the outer periphery of the recessed portion R₁₁₀ (e.g., separated from a sidewall of the recessed portion R₁₁₀). A distance between the barrier ring 602 and the IPD 500 may be substantially uniform around the periphery of the IPD 500. The barrier ring 602 may be formed of the same metallic material as the redistribution layers 113. Other metallic materials for the barrier ring 602 are within the contemplated scope of disclosure.

The package structure 100 may include a UBM dam structure 604 around the recessed portion R₁₁₀ on the board-side surface of the RDL structure 110. The UBM dam structure 604 may have a frame shape substantially similar to a frame shape of the barrier ring 602. The UBM dam structure 604 may be located between the solder balls 116 and the recessed portion R₁₁₀. A distance between the UBM dam structure 604 and the recessed portion Rio may be substantially uniform around the periphery of the recessed portion R₁₁₀. The UBM dam structure 604 may also be formed of the same metallic material as the redistribution layers 113. Other metallic materials for the UBM dam structure 604 are within the contemplated scope of disclosure.

Referring to FIG. 1C, the redistribution layers 113 may include a first redistribution layer 113-RDL1 located on a distal side of the proximal dielectric layer 114-DL1, a second redistribution layer 113-RDL2 located on a distal side of the intermediate dielectric layer 114-DL2 and a third redistribution layer 113-RDL3 located on a distal side of the intermediate dielectric layers 114-DL3 between the proximal dielectric layer 114-DL1 and distal dielectric layer 114-DL4.

The recessed portion R₁₁₀ may include a bottom surface R_{B} and a side surface R_{S} (e.g., sidewall of the recessed portion R₁₁₀). The side surface R_{S} may form a right angle with the bottom surface R_{B}. In at least one embodiment, the side surface R_{S} may form an obtuse angle (e.g., in a range from 91 degrees to 135 degrees) with the bottom surface R_{B}. The barrier ring 602 may be located near an intersection of the bottom surface R_{B} and the side surface R_{S}. In at least one embodiment, the barrier ring 602 may be separated from the side surface R_{S}.

The frontside RDL structure 110 may also include a contact via 110a in the intermediate dielectric layer 114-DL3. The contact via 110a may contact the second redistribution layer 113-RDL2. An upper surface of the contact via 110a may be substantially coplanar with the bottom surface R_{B} (i.e., when the package structure 100 is inverted) of the recessed portion R₁₁₀. The frontside RDL structure 110 may also include a bonding pad 110b on the contact via 110a. A width of the bonding pad 110b may be substantially equal to or greater than a width of the contact via 110a. The contact via 110a and the bonding pad 110b may be formed of the same metallic material as the redistribution layers 113. Other metallic materials for the contact via 110a and bonding pad 110b are within the contemplated scope of disclosure.

The IPD 500 may include a rectangular or square shape in the vertical cross-sectional view. Other shapes are within the contemplated scope of disclosure. The IPD 500 may include a first IPD side 500a facing the frontside RDL structure 110. The IPD 500 may also include a second IPD side 500b located opposite the first IPD side 500a and facing away from the frontside RDL structure 110. The IPD 500 may also include a third IPD side 500c connecting the first IPD side 500a and second IPD side 500b. The IPD 500 may also include a fourth IPD side 500d located opposite the third IPD side 500c and connecting the first IPD side 500a and second IPD side 500b. The IPD 500 may be located in an x-y plane that is substantially coplanar with an x-y plane of the frontside RDL structure 110.

The IPD 500 may include an IPD bonding pad 501 (e.g., copper pillar) located on the first IPD side 500a. A width of the IPD bonding pad 501 may be substantially equal to or greater than a width of the bonding pad 110b. The IPD bonding pad 501 may be formed of the same metallic material as the redistribution layers 113. Other metallic materials for the IPD bonding pad 501 are within the contemplated scope of disclosure.

The IPD 500 may be connected to the frontside RDL structure 110 by a solder bump 117 between the IPD bonding pad 501 and the bonding pad 110b on the bottom surface R_{B} of the recessed portion R₁₁₀. The solder bump 117 may be formed of a material substantially similar to a material of the solder balls 116.

The IPD underfill layer 229 may be formed on the bottom surface R_{B} of the recessed portion R₁₁₀. The IPD underfill layer 229 may be formed around the solder bump 117, the IPD bonding pad 501 and the bonding pad 110b. The IPD underfill layer 229 may fill an entirety of the recessed portion R₁₁₀. The IPD underfill layer 229 may contact the first IPD side 500a and the bottom surface R_{B} of the recessed portion R₁₁₀ and completely fill the space between the first IPD side 500a and the bottom surface R_{B} and bounded by the side surfaces R_{S}. As illustrated in FIG. 1D, a spreading of the IPD underfill layer 229 may be contained by the UBM dam structure 604. This may allow the UBM layer 111 (and the solder balls 116) to be formed much closer to the IPD 500 than in current package structures.

Referring to FIG. 1D, the recessed portion R₁₁₀ may include a width W_{R} in the x-direction in a range from 100 μm to 1000 μm. The recessed portion R₁₁₀ may also include a length in the y-direction (see FIG. 1B) in a range from 100 μm to 1000 μm. The width W_{R} of the recessed portion R₁₁₀ in the x-direction may be the same or different than the length of the recessed portion R₁₁₀ in the y-direction. A depth of the recessed portion R₁₁₀ in the z-direction may be substantially equal to a thickness T_{DL} of the distal dielectric layer 114-DL4. In at least one embodiment, both the thickness T_{DL} and the depth of the recessed portion R₁₁₀ may be in a range from 4 μm to 60 μm (e.g., about 15 μm).

The IPD 500 may include a width W₅₀₀ in the x-direction that is less than the width W_{R} of the recessed portion R₁₁₀. The width W_{R} of the recessed portion R₁₁₀ may be in a range from 50 μm to 500 μm. In at least one embodiment, the width W_{R} of the recessed portion R₁₁₀ is greater than or equal to 1.4 times the width W₅₀₀ of the IPD 500. The IPD 500 may include a thickness T₅₀₀ in the z-direction in a range from 20 μm to 70 μm (e.g., about 54 μm).

The barrier ring 602 may have a width W₆₀₂ in the x-direction in a range from 10 μm to 40 μm and a thickness T₆₀₂ in the z-direction in a range from 5 μm to 20 μm. The UBM dam structure 604 may also have a width W₆₀₄ in the x-direction in a range from 10 μm to 40 μm and a thickness T₆₀₄ in the z-direction in a range from 5 μm to 20 μm. The thickness T₆₀₄ of the UBM dam structure 604 may be sufficient to impede or contain a spread of the IPD underfill layer 229 along the board-side surface of the frontside RDL structure 110.

The first IPD side 500a may be separated from the bottom surface SB of the recessed portion R₁₁₀ by a distance D1 in a range from in a range from 4 μm to 120 μm. The first IPD side 500a may be separated from the backside surface of the frontside RDL structure 110 by a distance D2 that is less than 20 μm. In at least one embodiment, the first IPD side 500a may be located inside the recessed portion R₁₁₀ (e.g., D1<T_{DL}; D2<0).

A distance in the z-direction between the second IPD side 500b and the backside surface of the frontside RDL structure 110 may be less than or equal to 90 μm (e.g., about 79 μm) (e.g., D2+T₅₀₀≤90 μm). A distance D3 between a height of the second IPD side 500b in the z-direction and a height of a lower end of the solder ball 116 in the z-direction may be in a range from 20 μm to 40 μm (e.g., about 32 μm). A distance between the board-side surface of the frontside RDL structure 110 and the lower end of the solder ball 116 may be less than or equal to 120 μm (e.g., about 111 μm) (e.g., D2+T₅₀₀+D3≤120 μm).

A distance D4 in the x-direction between the UBM layer 111 and the side surface R_{S} of the recessed portion R₁₁₀ may be in a range from 20 μm to 100 μm. A distance D5 in the x-direction between the UBM layer 111 and the third IPD side 500c may be in a range from 50 μm to 150 μm. The distance D5 may also be considered to be the distance between the solder ball 116 and the third IPD side 500c. In at least one embodiment, the distance D5 may be less than 30% of the width W₅₀₀ of the IPD 500. The distance D5 may be referred to as a “keep out zone” (KOZ). By attaching the IPD 500 in the recessed portion R₁₁₀, a length of the KOZ (e.g., D5) in the embodiment package structures 100 may be less than a length of the KOZ in other package structures.

A distance D6 between the fourth IPD side 500d and the side surface R_{S} of the recessed portion R₁₁₀ may be in a range from 20 μm to 50 μm. A distance D7 between the fourth IPD side 500d and the side surface R_{S} of the recessed portion R₁₁₀ may be in a range from 20 μm to 50 μm. A distance D7 between the side surface R_{S} of the recessed portion R₁₁₀ and the UBM dam structure 604 may be in a range from 5 μm to 20 μm.

It should be noted that the dimensions referenced above with respect to FIG. 1D are intended to be illustrative and are not necessarily limiting the present disclosure.

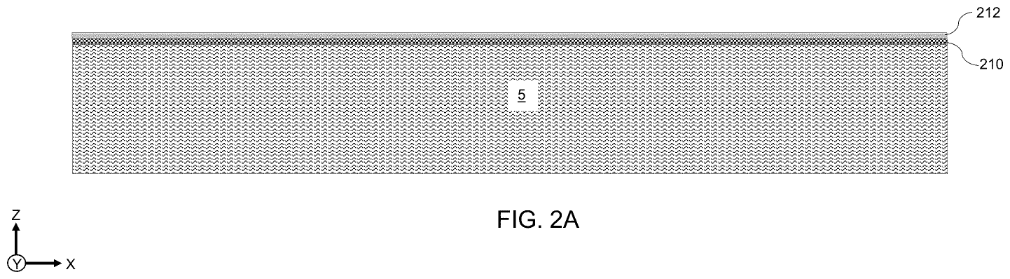

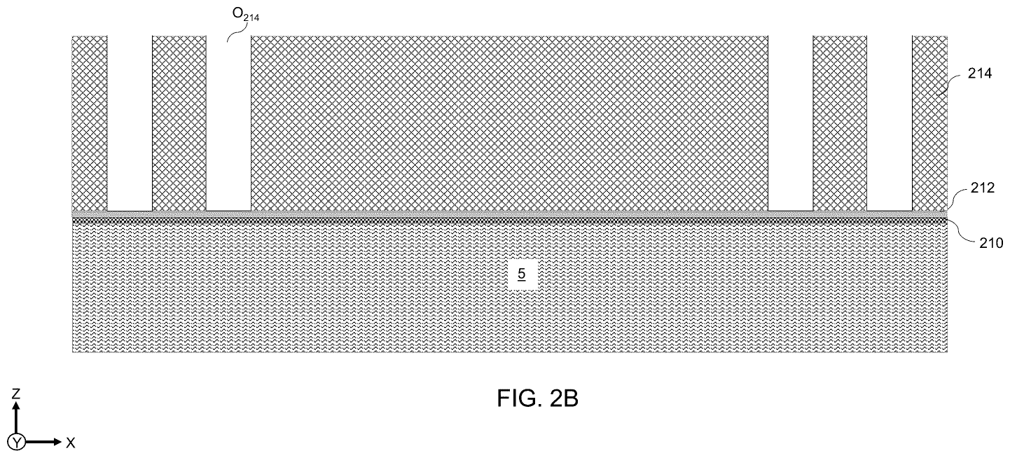

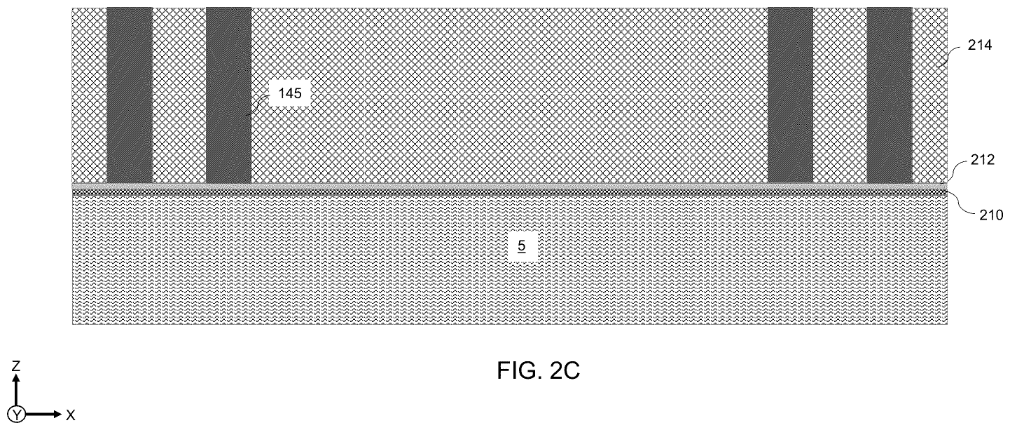

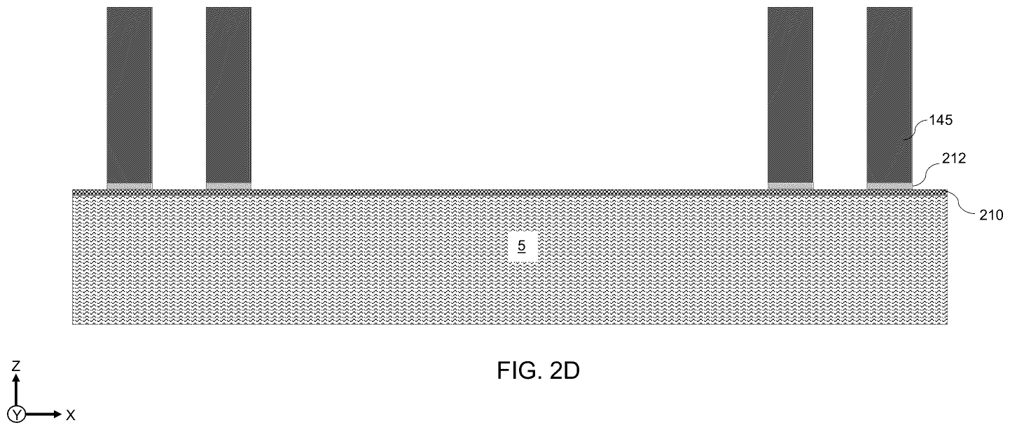

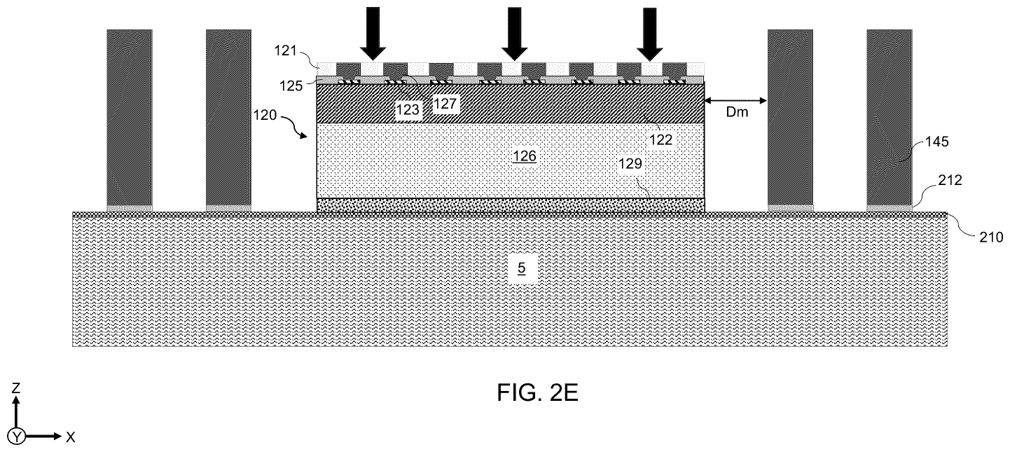

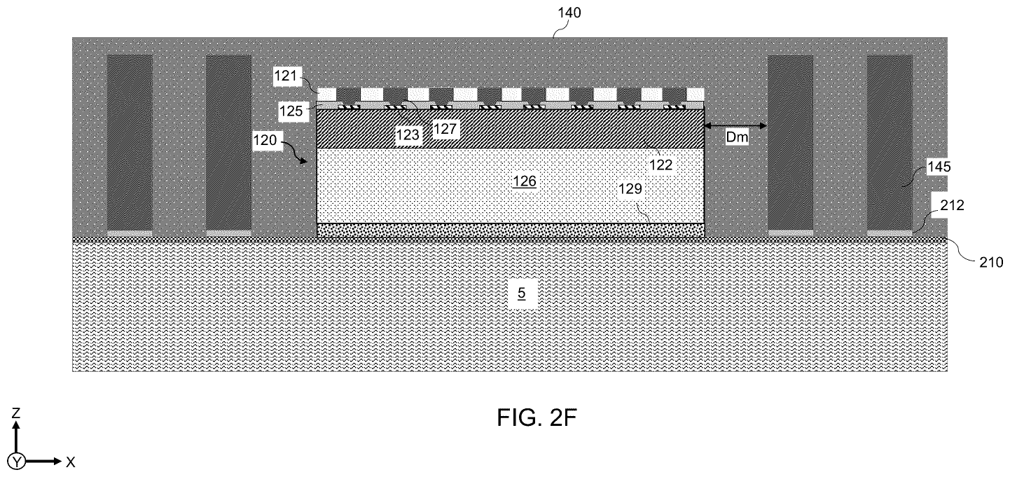

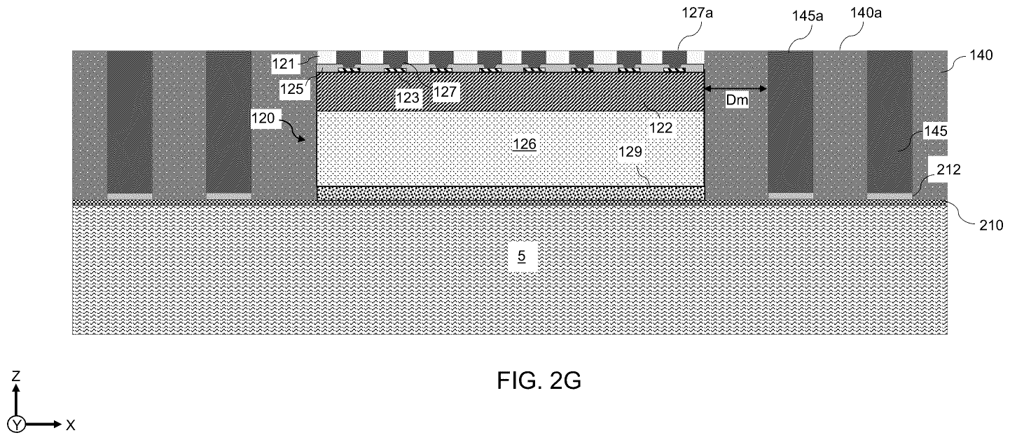

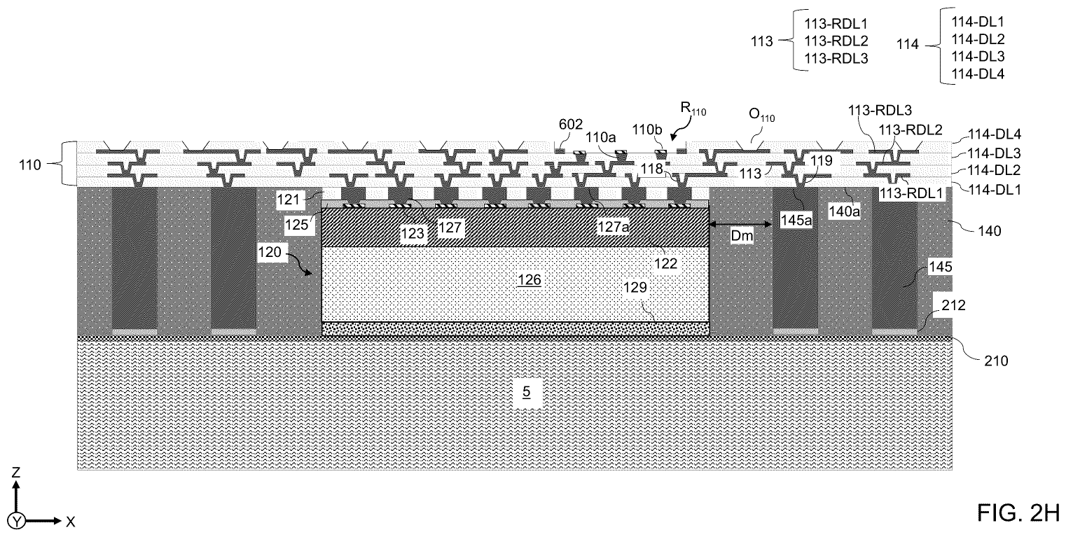

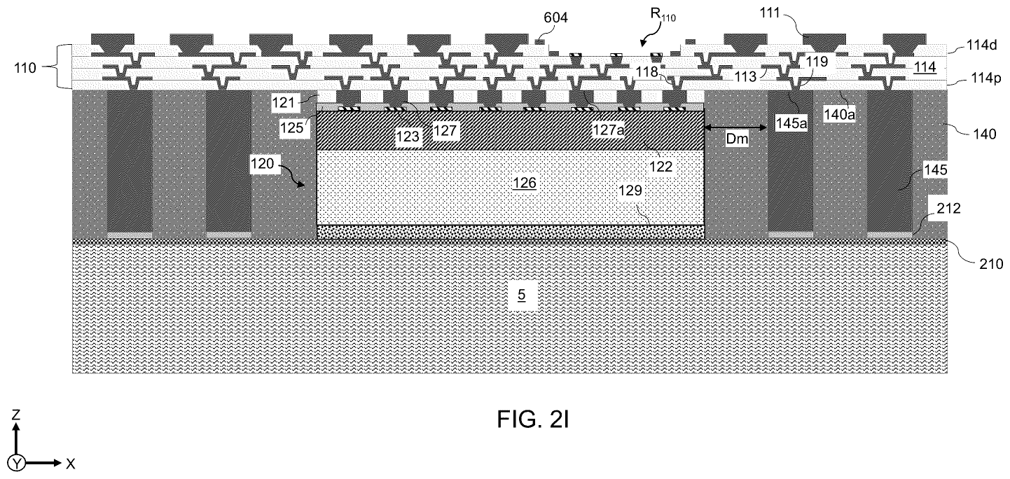

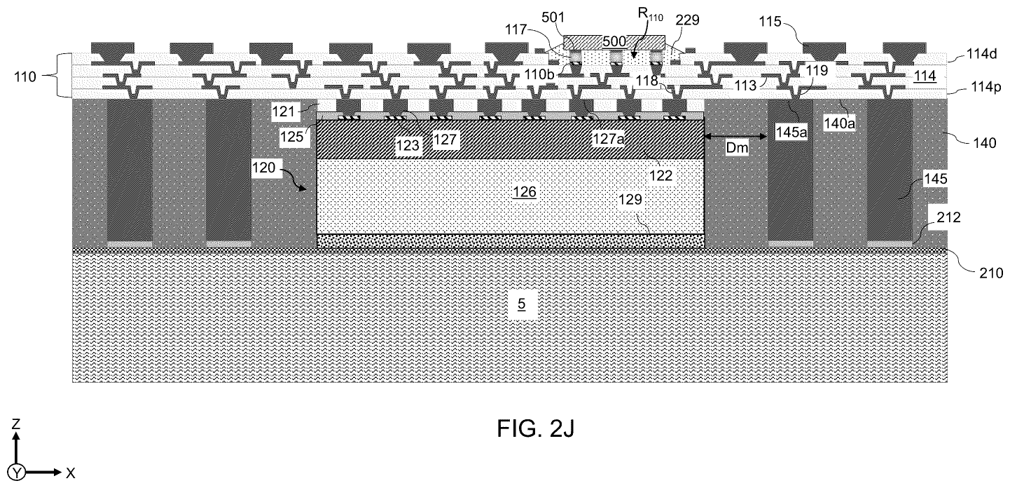

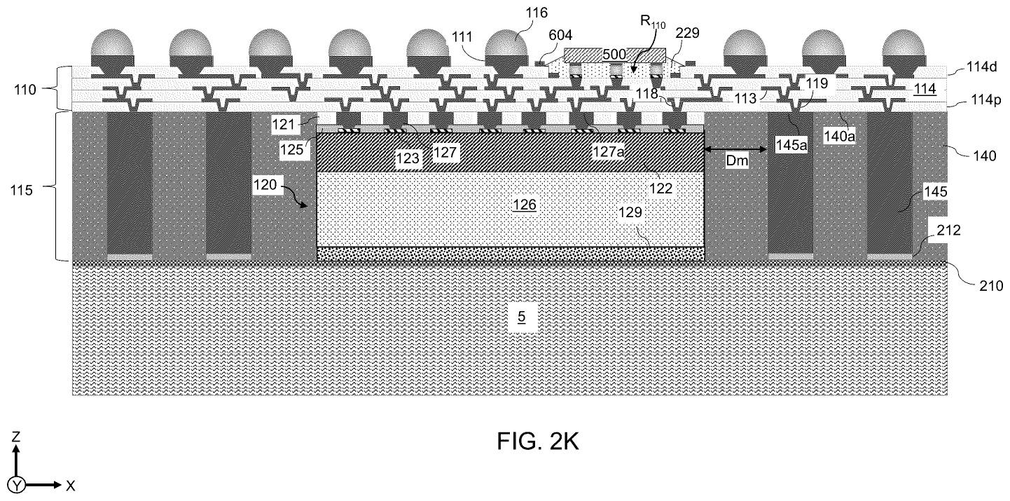

FIGS. 2A-2M are vertical cross-sectional views of various intermediate structures in a method of forming the package structure 100 according to one or more embodiments. In particular, FIG. 2A is a vertical cross-sectional view of an intermediate structure including a seed layer 212 on an adhesive layer 210 according to one or more embodiments.

As illustrated in FIG. 2A, an adhesive layer 210 may be formed on an upper surface of a carrier substrate 5. The carrier substrate 5 may include a semiconductor wafer (e.g., circular wafer or a rectangular wafer) or glass substrate. The lateral dimensions (such as the diameter of a circular wafer or a side of a rectangular wafer) of the carrier substrate 5 may be in a range from 100 mm to 500 mm, such as from 200 mm to 400 mm, although lesser and greater lateral dimensions may also be used. The carrier substrate 5 may be transparent or opaque. The thickness of the carrier substrate 5 may be sufficient to provide mechanical support to the package structure 100. For example, the thickness of the carrier substrate 5 may be in a range from 60 microns to 1 mm, although lesser and greater thicknesses may also be used.

The adhesive layer 210 may include a light-to-heat conversion (LTHC) layer or may include a thermally decomposing adhesive material. In at least one embodiment, the adhesive layer 210 may cover an entirety of the carrier substrate 5. The LTHC layer may include a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

A seed layer 212 (e.g., metallic seed layer, copper seed layer, etc.) may be formed on the adhesive layer 210. In at least one embodiment, the seed layer 212 may cover an entirety of the adhesive layer 210. The seed layer 212 may be formed, for example, by depositing the seed layer 212 in a deposition process such as CVD, PECVD, PVD, spin coating, lamination or other suitable deposition technique. The seed layer 212 may include, for example, one or more layers and may include one or more metals, metal alloys, and/or other metal-containing compounds (e.g., Cu, Al, Mo, Co, Ru, W, TIN, TaN, WN, etc.). Other suitable metal materials are within the contemplated scope of disclosure.

FIG. 2B is a vertical cross-sectional view of an intermediate structure including a photoresist layer 214 according to one or more embodiments. The photoresist layer 214 may be formed to have a thickness greater than a thickness of the first semiconductor die 120. The photoresist layer 214 may be patterned to form a pattern of openings O₂₁₄ through the photoresist layer 214. The bottom of the openings O₂₁₄ may be constituted by an upper surface of the seed layer 212. The photoresist layer 214 may be patterned, for example, by forming a mask layer (not shown) on an upper surface of the photoresist layer 214, and patterning the mask layer to have a pattern corresponding to the desired pattern in the photoresist layer 214. The photoresist layer 214 may then be patterned through the openings in the mask layer by an etching process (e.g., wet etching, dry etching, etc.) to form the openings O₂₁₄. The etching process may be performed until the upper surface of the seed layer 212 is exposed. The mask layer may then be removed to expose the upper surface of the photoresist layer 214.

FIG. 2C is a vertical cross-sectional view of an intermediate structure including the through vias 145 according to one or more embodiments. As illustrated in FIG. 2C, the through vias 145 may be formed in the openings O₂₁₄ in the photoresist layer 214. The through vias 145 may formed by electroplating a metallic fill material (such as copper) in the openings O₂₁₄ using the seed layer 212 which is exposed at the bottom of the openings O₂₁₄. The metal material for electroplating may include, for example, one or more layers and may include metals, metal alloys, and/or other metal-containing compounds (e.g., Cu, Al, Mo, Co, Ru, W, TIN, TaN, WN, etc.). Other suitable metal materials are within the contemplated scope of disclosure.

After the openings O₂₁₄ are filled with the metallic fill material, upper surfaces of the metallic fill material and the photoresist layer 214 may be planarized, for example, by chemical mechanical polishing (CMP) or another suitable planarization technique. After planarization, the upper surface of the metallic fill material (e.g., an upper surface of the through vias 145) may be substantially coplanar with an upper surface of the photoresist layer 214.

FIG. 2D is a vertical cross-sectional view of an intermediate structure including the through vias 145 according to one or more embodiments. After the upper surfaces of the metallic fill material constituting the through vias 145 and photoresist layer 214 are planarized, the photoresist layer 214 may then be removed, for example, by etching (e.g., wet etching, dry etching, etc.). The seed layer 212 (e.g., underbump metallization (UBM) layer) may also be etched (e.g., wet etching, dry etching, etc.) to expose an upper surface of the adhesive layer 210 between the through via 145.

The seed layer 212 may be etched concurrently in the same etching step with the photo resist layer 214, or in a separate step after the etching of the photoresist layer 214. As illustrated in FIG. 2D, after the etching of the seed layer 212, portions of the seed layer 212 may remain unetched beneath the through vias 145, respectively.

FIG. 2E is a vertical cross-sectional view of an intermediate structure including the first semiconductor die 120 according to one or more embodiments. The first semiconductor die 120 may be inverted so that the DAF 129 faces the adhesive layer 210 and then placed on the adhesive layer 210. An entirety of the upper surface of the DAF 129 may contact the upper surface of the adhesive layer 210. In at least one embodiment, the first semiconductor die 120 may be placed on the upper surface of the adhesive layer 210 by a pick-and-place (PnP) process (e.g., a robotic PnP process).

The first semiconductor die 120 may be placed on the adhesive layer 210 so that a minimum distance Dm (e.g., 100 μm) is maintained between the DAF 129 and an adjacent through via 145 around the periphery of the first semiconductor die 120. A pressing force (indicated by the directional arrows in FIG. 2E) may then be applied to the first semiconductor die 120 to press the DAF 129 onto the surface of the adhesive layer 210. The intermediate structure may then be heated (e.g., in an oven) to securely fix the DAF 129 to the surface of the adhesive layer 210. As illustrated in FIG. 2E, a height of the through vias 145 may be greater than a height of first semiconductor die 120.

FIG. 2F is a vertical cross-sectional view of an intermediate structure including the lower encapsulation layer 140 according to one or more embodiments. The lower encapsulation layer 140 may be formed by a sequence of an over-molding process and a planarization process. In particular, the lower encapsulation layer 140 (e.g., an epoxy molding compound (EMC)) may be formed over the adhesive layer 210 to fill in the gaps between the first semiconductor die 120 and the through vias 145 and encapsulate the first semiconductor die 120 and the through vias 145. The lower encapsulation layer 140 may be formed to have a height greater than a height of the through vias 145. The lower encapsulation layer 140 may be formed, for example, by a deposition process such as CVD, PECVD, PVD, spin coating, lamination or other suitable deposition technique.

FIG. 2G is a vertical cross-sectional view of an intermediate structure including the lower encapsulation layer 140 after performing the planarization process, according to one or more embodiments. As illustrated in FIG. 2G, the planarization process may be performed on a surface 140a of the lower encapsulation layer 140 until an upper surface 145a of the through vias 145 and an upper surface 127a of the semiconductor die bonding pads 127 are exposed. That is, the planarization process may be performed until the surface 140a of the lower encapsulation layer 140 is substantially coplanar with the upper surface 145a of the through vias 145 and the upper surface 127a of the semiconductor die bonding pads 127. The planarization process may include, for example, a mechanical grinding process and/or a chemical mechanical polishing (CMP) process.

FIG. 2H is a vertical cross-sectional view of an intermediate structure including the frontside RDL structure 110, according to one or more embodiments. The dielectric layers 114 and redistribution layers 113 may be alternatingly formed in a series of process steps. In particular, the proximal dielectric layer 114-DL1 may be formed on the lower encapsulation layer 140. The proximal dielectric layer 114-DL1 may be formed, for example, by a deposition process such as CVD, PECVD, PVD, spin coating, lamination or other suitable deposition technique.

Openings may be formed in the proximal dielectric layer 114-DL1 (e.g., by etching in a photolithographic process). The first redistribution layer 113-RDL1 may then be formed (e.g., by an electroplating process) in the openings and on the proximal dielectric layer 114-DL1 (as referred to as proximal dielectric layer 114p). In this manner, the vias 118 (e.g., RDL bonding pads) may be formed so as to contact the semiconductor die bonding pads 127, and the vias 119 (e.g., frontside bonding pads) may be formed so as to contact the through vias 145.

The remaining dielectric layers 114 and redistribution layers 113 of the frontside RDL structure 110 may then be alternatingly formed in a similar manner. In particular, during the forming of the third redistribution layer 113-RDL3, a plurality of openings may be formed at a location of the recessed portion R₁₁₀ in the intermediate dielectric layer 114-DL3. Then, as metal material (e.g., copper) is deposited on the intermediate dielectric layer 114-DL3 to form the third redistribution layer 113-RDL3, the metal material may be formed in the openings to form the contact vias 110a in contact the second redistribution layer 113-RDL2. The metal material may also be formed on the distal surface of the intermediate dielectric layer 114-DL3 to form the barrier ring 602 and to form the bonding pads 110b in contact with the contact vias 110a. The metal material may then be patterned (e.g., by etching in a photolithographic process) to complete the formation of the contact vias 110a, the bonding pads 110b the barrier ring 602 and the third redistribution layer 113-RDL3. Thus, in at least one embodiment, the contact vias 110a, bonding pads 110b, barrier ring 602 and third redistribution layer 113-RDL3 may all be formed concurrently and using the same metal material.

The distal dielectric layer 114-DL4 may then be formed on the intermediate dielectric layer 114-DL3 and on the third redistribution layer 113-RDL3. Openings O₁₁₀ may then be formed (e.g., by a photolithographic process) in the distal dielectric layer 114-DL4 so as to expose an upper surface of the third redistribution layer 113-RDL3. Concurrently with the forming of the openings O₁₁₀, the recessed portion R₁₁₀ may be formed in the distal dielectric layer 114-DL4. Thus, in at least one embodiment, the openings O₁₁₀ and recessed portion R₁₁₀ may be formed concurrently using the same etching process.

FIG. 2I is a vertical cross-sectional view of an intermediate structure including the UBM layer 111, according to one or more embodiments. As illustrated in FIG. 2I, the UBM dam structure 604 may be formed on a surface of the distal dielectric layer 114-DL4. The UBM dam structure 604 may be formed, for example, by a photolithographic process in which a photoresist layer (not shown) is deposited on the distal dielectric layer 114-DL4 (also referred to as distal dielectric layer 114d) and patterned to form openings in the photoresist layer corresponding to the UBM dam structure 604. Metal material may then be deposited in the openings to form the UBM dam structure 604 on the distal dielectric layer 114-DL4. The photoresist layer may then be removed from the surface of the distal dielectric layer 114-DL4 (e.g., by ashing or other suitable process). The UBM layers 111 may then be formed (e.g., by an electroplating process) in the openings O₁₁₀ (e.g., see FIG. 2H) in the distal dielectric layer 114-DL4. It should be noted that in at least one embodiment, the order of formation may be reversed so that the UBM layers 111 are formed before the UBM dam structure 604.

FIG. 2J is a vertical cross-sectional view of an intermediate structure including the IPD 500, according to one or more embodiments. The IPD 500 may be formed together with the solder bump 117 on the IPD bonding pad 501. The IPD 500 may then be connected to the frontside RDL structure 110 in the recessed portion R₁₁₀. In particular, the IPD 500 may be moved to a position over the recessed portion R₁₁₀. The IPD 500 may be moved, for example, using an electromechanical pick-and-place (PNP) machine. The solder bumps 117 may then be lowered into the recessed portion R₁₁₀ and onto the bonding pads 110b, respectively. The intermediate device may then be heated to reflow the solder bumps 117 on the bonding pads 110b, respectively.

The IPD underfill layer 229 (e.g., epoxy-based polymeric material) may then be dispensed (e.g., injected) into the recessed portion R₁₁₀. The IPD underfill layer 229 may be formed continuously under an entirety of the upper package IPD 500. The IPD underfill layer 229 may be dispensed up until the time that the IPD underfill layer 229 contacts the UBM dam structure 604, at which time the dispensing may be ceased. The IPD underfill layer 229 may then be cured, for example, in a box oven for duration in a range from 60 minutes to 120 minutes at a temperature in a range from 120° C. to 180° C. to provide the IPD underfill layer 229 with a sufficient stiffness and mechanical strength.

FIG. 2K is a vertical cross-sectional view of an intermediate structure including the solder balls 116, according to one or more embodiments. After the formation of the UBM layers 111, the solder balls 116 may be formed on the UBM layers 111, respectively. It should be noted that the solder balls 116 may be formed on the UBM layers 111 either before or after the IPD 500 is connected to the frontside RDL structure 110. The solder balls 116 may be formed, for example, by a suitable process such as reflow, evaporation, ball drop, screen printing, or electroplating.

After the solder balls 116 are formed on the UBM layer 111, the intermediate structure may be inverted and placed on a carrier tape (not shown). The carrier tape may include a thin, flexible strip made of plastic. The carrier tape may optionally include a pattern of pockets or cavities that precisely match the arrangement of the solder balls 116 on the intermediate structure. The intermediate structure may be positioned so that each solder ball 116 sits within its corresponding pocket. A cover tape (not shown) may then be applied over the carrier tape, sealing the solder balls 116 within their respective pockets. The cover tape may be made of transparent plastic and securely bonded to the carrier tape, creating a protective barrier.

The intermediate structure may then be debonded from the carrier substrate 5. The intermediate structure may be debonded from the carrier substrate 5, for example, by decomposing (e.g., by using heat, ultraviolet (UV) light, etc.) the adhesive layer 210 that adhered the carrier substrate 5 to a surface of the intermediate structure. An LTHC cleaning step (e.g., post-laser drill clean) or other suitable cleaning process may then be performed in order to clean the surface of the intermediate structure. The cleaning process may help to ensure that all of the adhesive material from the adhesive layer 210 has been removed from the surface of the intermediate structure.

A plurality of the intermediate structures may be formed together in a wafer level process. In that case, the plurality of intermediate structures may be separated into individual units (e.g., into a plurality of package structures 100). In at least one embodiment, the intermediate structures may be separated by using a dicing saw. The dicing saw may saw along dicing lines located between the intermediate structures. This may complete the formation of a plurality of the package structures 100.

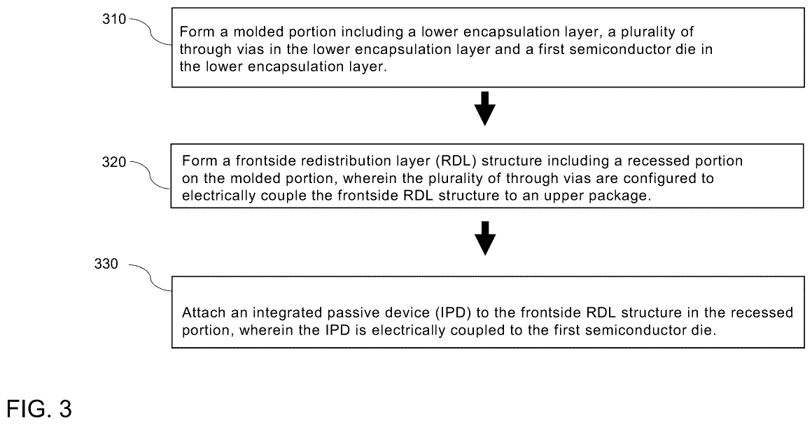

FIG. 3 is a flow chart illustrating a method of forming a package structure 100, according to one or more embodiments. Step 310 of the method may include forming a molded portion 115 including a lower encapsulation layer 140, a plurality of through vias 145 in the lower encapsulation layer 140 and a first semiconductor die 120 in the lower encapsulation layer 140. Step 320 may include forming a frontside redistribution layer (RDL) structure 110 including a recessed portion R₁₁₀ on the molded portion 115, wherein the plurality of through vias 145 are configured to electrically couple the frontside RDL structure 110 to an upper package. Step 330 may include attaching an IPD 500 to the frontside RDL structure 110 in the recessed portion R₁₁₀, wherein the IPD 500 is electrically coupled to the first semiconductor die 120.

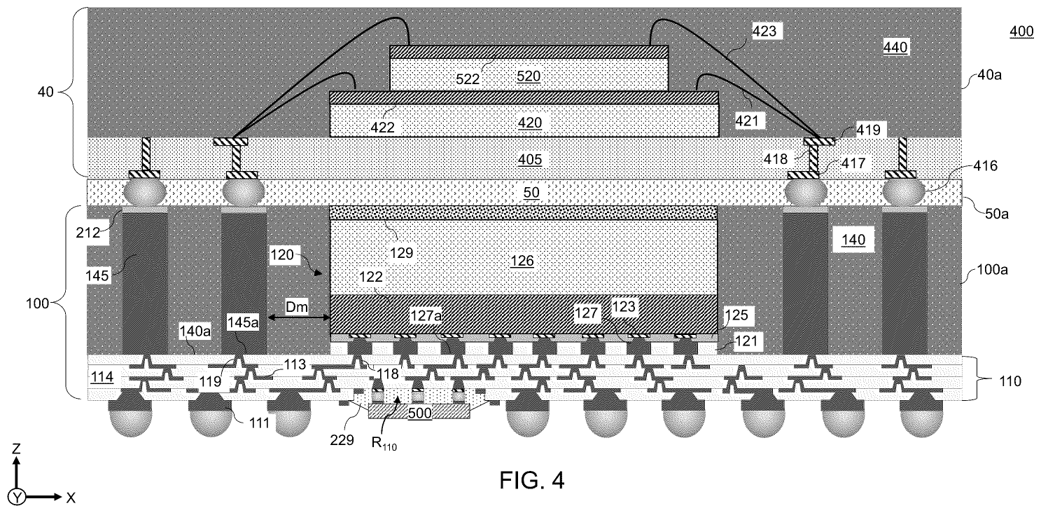

FIG. 4 is a vertical cross-sectional view of a semiconductor device 400 including an upper package 40 on the package structure 100 according to one or more embodiments. The semiconductor device 400 may be referred to as a “package-on-package structure.”

The upper package 40 may include a sidewall 40a substantially aligned with a sidewall 100a of the package structure 100. The upper package 40 may include a package substrate 405. The package substrate 405 may include a core substrate or core less substrate. The package substrate 405 may include one or more dielectric layers stacked in a thickness direction of the package substrate 405. In at least one embodiment, the package substrate 405 may include a build-up film substrate such as an Ajinomoto build-up film (ABF) substrate. In at least one embodiment, the package substrate includes one or more layers of epoxy resin such as a bismaleimide triazine epoxy (BT epoxy), and dielectric polymer material such as polyimide (PI), benzocyclo-butene (BCB), or polybenzobisoxazole (PBO). Other suitable dielectric materials for the package substrate 405 are within the contemplated scope of disclosure.

The package substrate 405 may include bottom contact pads 417 on a bottom surface of the package substrate 405. The package substrate may include upper contact pads 419 on an upper surface of the package substrate 405. The upper contact pads 419 may be electrically connected to the bottom contact pads 417 through one or more interconnect structures 418 (e.g., metal traces and metal vias) in the package substrate 405.

The semiconductor device 400 may also include a plurality of solder balls 416 for attaching the upper package 40 to the package structure 100. The solder balls 416 may be located on the seed layer 212 in the package structure 100. The bottom contact pads 417 in the upper package 40 may contact the solder balls 416 on the seed layer 212. The upper package 40 may be electrically coupled to the package structure 100 (e.g., electrically coupled to the frontside RDL structure 110) through the solder balls 416.

The upper package 40 may also include a first upper semiconductor die 420 (e.g., second semiconductor die) mounted on the package substrate 405 (e.g., by hybrid bonding, die attach film, etc.). A centerpoint (in the x-y plane) of the first upper semiconductor die 420 may be substantially aligned in the z-direction with a centerpoint (in the x-y plane) of the first semicondutor die 120 in the package structure 100. The first upper semiconductor die 420 may include an active region 422 connected to the upper contact pads 419 through one or more wires 421.

The upper package 40 may also include a second upper semiconductor die 520 (e.g., third semiconductor die) mounted on the first upper semiconductor die 420 (e.g., by hybrid bonding, die attach film, etc.). The second upper semiconductor die 520 may have a width in the x-direction that is less than a width in the x-direction of the first upper semiconductor die 420. The second upper semiconductor die 520 may include an active region 522 connected to the upper contact pads 419 through one or more wires 423. Each of the first upper semiconductor die 420 and the second upper semiconductor die 520 may be similar in design and/or function to the first semiconductor die 120 in the package structure 100 as described above. In at least one embodiment, each of the first upper semiconductor die 420 and the second upper semiconductor die 520 may include a dynamic random access memory (DRAM) die.

The upper package 40 may also include an upper encapsulation layer 440 similar to the lower encapsulation layer 140 in the package structure 100. The upper encapsulation layer 440 may be formed on the package substrate 405 and may substantially encapsulate the first upper semiconductor die 420, the second upper semiconductor die 520, the wires 421 and the wires 423.

As further illustrated in FIG. 4, the semiconductor device 400 may also include a thermally conductive underfill layer 50 between the upper package 40 and the package structure 100. A sidewall 50a of the thermally conductive underfill layer 50 may be substantially aligned with the sidewall 40a of the upper package 40 and the sidewall 100a of the package structure 100. The thermally conductive underfill layer 50 may be formed around the solder balls 416 and substantially fill the gap (e.g., space) between the bottom surface of the package substrate 405 in the upper package 40 and the upper surfaces of the lower encapsulation layer 140, seed layer 212 and DAF 129 in the package structure 100. The thermally conductive underfill layer 50 may enhance heat dissipation and thermal performance by improving the thermal conductivity (e.g., enhance heat transfer) between the first semiconductor die 120 and the package substrate 405.

The thermally conductive underfill layer 50 may help to affix the upper package 40 to the package structure 100. The thermally conductive underfill layer 50 may have a low viscosity (e.g., less than about 5,000 cP at 10 rpm), and may be formed of an epoxy-based polymeric material. In at least one embodiment, the thermally conductive underfill layer 50 may include a capillary underfill including a mixture of epoxy and silica. In at least one embodiment, the thermally conductive underfill layer 50 may include a low-viscosity suspension of silica in prepolymer.

In at least one embodiment, the thermally conductive underfill layer 50 may have a thermal conductivity greater than 20 W/m·K. The thermally conductive underfill layer 50 may include, for example, a filled polymer underfill. The filled polymer underfill may include thermally conductive fillers such as ceramic particles, metal particles, or carbon fibers suspended within a polymer material (e.g., polymer matrix). It should be noted that an underfill material may be modified to be a high-k underfill material by adding a higher percentage of filler (e.g., metal filler) or changing the high-k thermally conductive fillers in the underfill material.

The upper package 40 may be fabricated by a process in which the first upper semiconductor die 420 (e.g., second semiconductor die) is mounted on the package substrate 405. A pick-and-place machine may be used to locate the first upper semiconductor die 420 over the package substrate 405 so as to be subsequently aligned with the first semiconductor die 120. The first upper semiconductor die 420 may be attached to the package substrate 650 by a die attach film, by hybrid bonding or by other suitable bonding methods.

The second upper semiconductor die 520 (e.g., third semiconductor die) may then be mounted on the first upper semiconductor die 420. The pick-and-place machine may also be used to locate the second upper semiconductor die 520 over the first upper semiconductor die 420. The second upper semiconductor die 520 may be attached to the first upper semiconductor die 420 by a die attach film, by hybrid bonding or by other suitable bonding methods. Ends of the wires 421 and wires 423 may then be attached (e.g., by soldering) to the active region 422 of the first upper semiconductor die 420 and to the active region 522 of the second upper semiconductor die 520, respectively. The other ends of the wires 421 and wires 423 may then be attached (e.g., by soldering) to the upper contact pads 419. The upper encapsulation layer 440 may then be formed on the package substrate 405 in a manner similar to the method of forming the lower encapsulation layer 140 describes above. The solder balls 416 may then be formed on the lower contact pads 417 in a manner similar to the method of forming the solder balls 116.

After the upper package 40 is fabricated, the upper package 40 may be mounted on the package structure 100. In at least one embodiment, the upper package 40 may be mounted on the package structure 100 in a wafer-level process before the wafer including a plurality of the package structures 100 is separated (e.g., by a dicing saw) into a plurality of individual units.

The upper package 40 may be mounted on the package structure 100 by a pick-and-place machine. The pick-and-place machine may be used to locate the upper package 40 over the package structure 100 so as to align the solder balls 416 with the portions of seed layer 212 on the through vias 145. The pick-and-place machine may then lower the upper package 40 onto the package structure 100, and heat and/or pressure may be applied to reflow the solder balls 416 and bond the upper package 40 to the package structure 100.

The thermally conductive underfill layer 50 (e.g., epoxy-based polymeric material) may then be dispensed (e.g., injected) onto the upper surface of the package structure 100, under the package substrate 405 and around the solder balls 416. As illustrated in FIG. 4, the thermally conductive underfill layer 50 may be formed continuously under an entirety of the upper package 60. The thermally conductive underfill layer 50 may then be cured, for example, in a box oven for duration in a range from 60 minutes to 120 minutes at a temperature in a range from 120° C. to 180° C. to provide the thermally conductive underfill layer 50 with a sufficient stiffness and mechanical strength.

After the thermally conductive package underfill 50 has cured, the intermediate structure may be separated into individual units (e.g., into a plurality of semiconductor devices 400). In at least one embodiment, the plurality of semiconductor devices 400 may be separated by using a dicing saw.

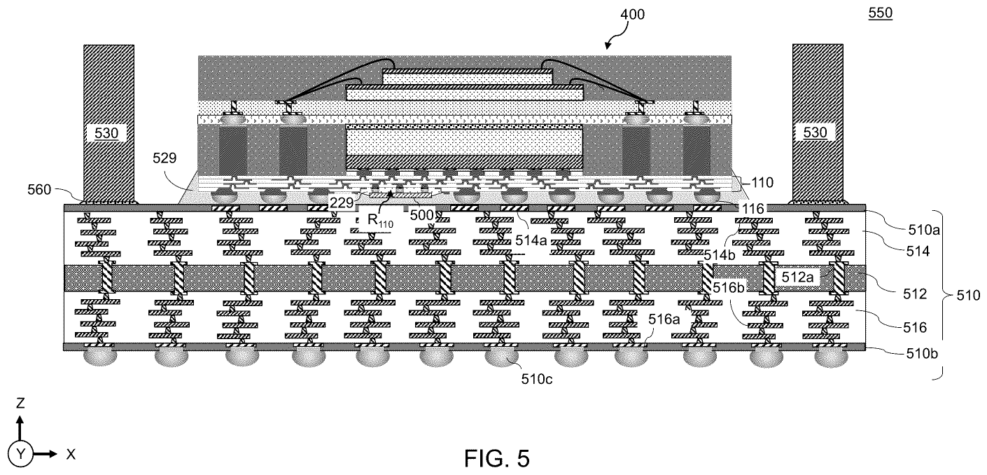

FIG. 5 is a vertical cross-sectional view of a semiconductor package 550 including the semiconductor device 400 on a package substrate 510 according to one or more embodiments. The package substrate 510 may include, for example, a core 512, a package substrate upper dielectric layer 514 formed on the core 512 (e.g., a first side or chip-side of the package substrate 510), and a package substrate lower dielectric layer 516 formed on the core 512 (e.g., a second side or board-side of the package substrate 510). In particular, the package substrate 510 may include a build-up film substrate such as an Ajinomoto build-up film (ABF) substrate. That is, in at least one embodiment, each of the package substrate upper dielectric layer 514 and the package substrate lower dielectric layer 516 may be described as an ABF layer.

The core 512 may provide rigidity to the package substrate 510. The core 512 may include, for example, an epoxy resin such as a bismaleimide triazine epoxy (BT epoxy) and/or a woven glass laminate. The core 512 may alternatively or in addition include an organic material such as a polymer material. In particular, the core 512 may include a dielectric polymer material such as polyimide (PI), benzocyclo-butene (BCB), or polybenzobisoxazole (PBO). Other suitable dielectric materials are within the contemplated scope of disclosure.

The core 512 may include one or more through vias 512a. The one or more through vias 512a may extend from a lower surface of the core 512 to an upper surface of the core 512. The one or more through vias 512a may allow an electrical connection between the package substrate upper dielectric layer 514 and the package substrate lower dielectric layer 516. The one or more through vias 512a may include, for example, one or more layers and may include metals, metal alloys, and/or or other metal-containing compounds (e.g., Cu, Al, Mo, Co, Ru, W, TiN, TaN, WN, etc.). Other suitable metal materials are within the contemplated scope of disclosure.

The package substrate lower dielectric layer 516 may include a plurality of layers and, in particular, may include a build-up film (e.g., ABF). The package substrate lower dielectric layer 516 may include an organic material such as a polymer material. In particular, the package substrate lower dielectric layer 516 may include one or more layers of dielectric polymer material such as polyimide (PI), benzocyclobutene (BCB), or polybenzobisoxazole (PBO). Other suitable dielectric materials are within the contemplated scope of disclosure.

The package substrate lower dielectric layer 516 may include one or more package substrate lower bonding pads 516a on a board-side surface of the package substrate lower dielectric layer 516. In particular, the package substrate lower bonding pads 516a may be exposed on the board-side surface of the package substrate lower dielectric layer 516. The package substrate lower dielectric layer 516 may also include one or more metal interconnect structures 516b. The metal interconnect structures 516b may be connected to the package substrate lower bonding pads 516a and the through vias 512a in the core 512. The metal interconnect structures 516b may include metal layers (e.g., copper traces) and metal vias connecting the metal layers. The package substrate lower bonding pads 516a and the metal interconnect structures 516b may include, for example, one or more layers and may include metals, metal alloys, and/or or other metal-containing compounds (e.g., Cu, Al, Mo, Co, Ru, W, TiN, TaN, WN, etc.). Other suitable metal materials for use in the metal interconnect structures 516b are within the contemplated scope of disclosure.

A package substrate lower surface layer 510b may be formed on the board-side surface of the package substrate lower dielectric layer 516. The package substrate lower surface layer 510b may partially cover the package substrate lower bonding pads 516a. The package substrate lower surface layer 510b may include one or more of a passivation layer and protection layer. The package substrate lower surface layer 510b may include, for example, a dielectric polymer material such as polyimide (PI), benzocyclobutene (BCB), or polybenzobisoxazole (PBO). The package substrate lower surface layer 510b may alternatively or additionally include silicon oxide, silicon nitride, low-k dielectric materials such as carbon-doped oxides, extremely low-k dielectric materials such as porous carbon doped silicon dioxide, or a combination thereof. Other suitable dielectric materials are within the contemplated scope of disclosure.

A ball-grid array (BGA) including a plurality of solder balls 510c may be formed on the board-side surface of the package substrate lower dielectric layer 516. The solder balls 510c may allow the semiconductor package 550 to be securely mounted on a substrate such as a printed circuit board (PCB) and electrically coupled to the PCB substrate. The solder balls 510c may contact the package substrate lower bonding pads 516a, respectively.

The package substrate upper dielectric layer 514 may be formed on an upper surface of the core 512. The package substrate upper dielectric layer 514 may also include a plurality of layers and, in particular, may include a build-up film (e.g., ABF). The package substrate upper dielectric layer 514 may also include an organic material such as a polymer material. In particular, the package substrate upper dielectric layer 514 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 514 may include one or more package substrate upper bonding pads 514a on a chip-side surface of the package substrate upper dielectric layer 514. In particular, the package substrate upper bonding pads 514a may be exposed on the chip-side surface of the package substrate upper dielectric layer 514. In at least one embodiment, a bonding pad surface layer (not shown) (e.g., one or more layers of metals (e.g., tin, nickel, palladium, gold, etc.) and/or other materials) may be formed on the package substrate upper bonding pads 514a to improve solder joint reliability.

The package substrate upper dielectric layer 514 may also include one or more metal interconnect structures 514b. The metal interconnect structures 514b may include metal layers (e.g., copper traces) and metal vias connecting the metal layers. The package substrate upper bonding pads 514a may be electrically connected to the solder balls 510c of the BGA by way of the metal interconnect structures 514b, the through vias 512a, the metal interconnect structures 516b, and the package substrate lower bonding pads 516a. The package substrate upper bonding pads 514a and the metal interconnect structures 514b may include, for example, one or more layers and may include metals, metal alloys, and/or or other metal-containing compounds (e.g., Cu, Al, Mo, Co, Ru, W, TiN, TaN, WN, etc.). Other suitable metal materials are within the contemplated scope of disclosure.

A package substrate upper surface layer 510a may be formed on the chip-side surface of the package substrate upper dielectric layer 514. The package substrate upper surface layer 510a may including a coating layer, laminate layer, etc. The package substrate upper surface layer 510a may be formed so as to at least partially cover the package substrate upper bonding pads 514a.

In at least one embodiment, the package substrate upper surface layer 510a may include a solder resist layer (e.g., solder mask layer). The solder resist layer may include a thin layer of polymer material (e.g., epoxy polymer). The solder resist layer may have a thickness in a range from about 5 μm to 50 μm. In at least one embodiment, the solder resist layer may have a thickness in a range from about 10 μm to 30 μm. Greater or lesser thickness of the solder resist layer may be used. The solder resist layer may be formed so as to cover the package substrate upper bonding pads 514a and other metal features (e.g., conductive lines, copper traces) on the chip-side surface of the package substrate 510. The solder resist layer may protect the package substrate upper bonding pads 514a and other metal features from oxidation. The solder resist layer may also inhibit (e.g., prevent) solder bridges (e.g., unintended electrical connections) from forming between closely spaced metal features. The solder resist layer may include solder resist openings (SROs) over the package substrate upper bonding pads 514a, respectively. An upper surface of the package substrate upper bonding pads 514a may be exposed through the SROs. The SROs may have a tapered sidewall so that a diameter of the SRO (in the X-Y plane) may decrease in a direction toward the package substrate upper bonding pad 514a.

The package substrate upper surface layer 510a may alternatively or additionally include a layer other than a solder resist layer, such as a passivation layer or protection layer. In particular, the package substrate upper surface layer 510a may alternatively or additionally include a dielectric polymer material such as polyimide (PI), benzocyclo-butene (BCB), or polybenzobisoxazole (PBO), silicon oxide, silicon nitride, low-k dielectric materials such as carbon-doped oxides, extremely low-k dielectric materials such as porous carbon doped silicon dioxide, a combination thereof or other suitable material. The package substrate upper surface layer 510a may alternatively or additionally be formed, for example, by chemical vapor deposition (CVD), physical vapor deposition (PVD), spin coating, lamination or other suitable deposition technique.

The semiconductor device 400 may be mounted on the package substrate 110 by attaching the solder balls 116 (e.g., BGA) to the package substrate upper bonding pads 514a in the package substrate 510. A package underfill layer 529 may be formed under and around the semiconductor device 400 and the solder balls 116 so as to fix the semiconductor device 400 to the package substrate 510. The package underfill layer 529 may be formed of an epoxy-based polymeric material.

As illustrated in FIG. 5, the package underfill layer 529 may be formed on the IPD underfill layer 229. The package underfill layer 529 may also be formed on an exposed portion of the IPD 500 (e.g., a portion not covered by the IPD underfill layer 229).

The semiconductor package 550 may also include a stiffener ring 530 that may be fixed to the package substrate 510 by an adhesive 560 such as a silicone adhesive or an epoxy adhesive. Other adhesives are within the contemplated scope of this disclosure. The stiffener ring 530 may be formed of a metal such as copper with a nickel coating, or an aluminum alloy. The stiffener ring 530 may alternatively be formed of a ceramic material or hard plastic (polymer) material. The stiffener ring 530 may be formed on the package substrate 510 so as to surround (e.g., encircle) the semiconductor device 400 in the x-y plane. The stiffener ring 530 may extend in a substantially perpendicular direction (e.g., in the z-direction) from the package substrate 510. The stiffener ring 530 may help to provide rigidity to the package substrate 510 and semiconductor device 400.

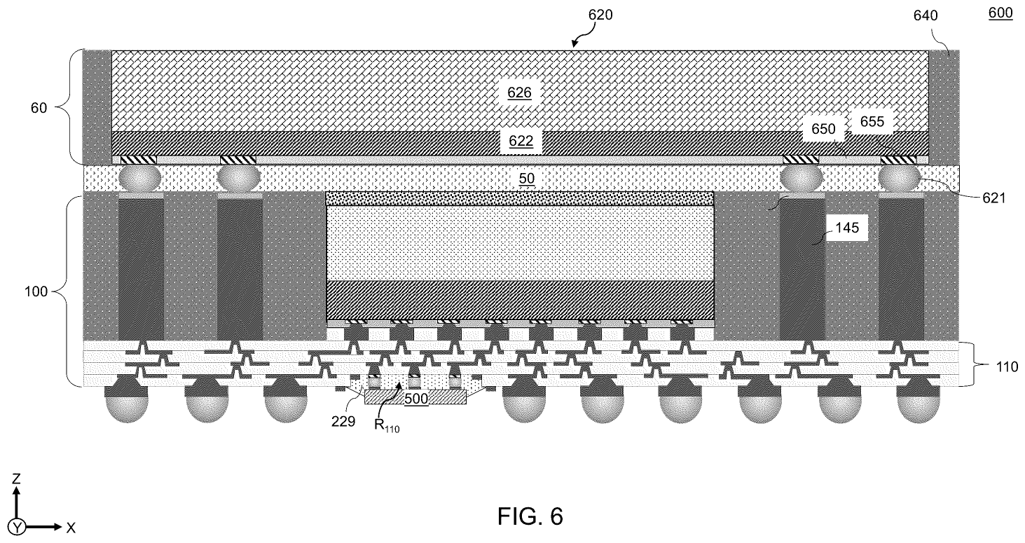

FIG. 6 is a vertical cross-sectional view of a semiconductor device 600 according to one or more embodiments. The semiconductor device 600 may be substantially similar to the semiconductor device 400 in FIG. 4. However, in the semiconductor device 600, the upper package 40 may be replaced with an upper package 60 that includes an upper semiconductor die 620. The upper semiconductor die 620 may be substantially the same as the first semiconductor die 120. In at least one embodiment, the upper semiconductor die 620 may include a memory die such as a DRAM die.

The upper semiconductor die 620 may be encapsulated in an upper encapsulation layer 640. The upper encapsulation layer 640 may be substantially similar to the lower encapsulation layer 140 (e.g., see FIG. 1A). It should be noted that the semiconductor device 400 may be replaced by the semiconductor device 600 in an alternative design of the semiconductor package 550 in FIG. 5.

The upper semiconductor die 620 may be flip-chip mounted on the package structure 100. The upper semiconductor die 620 may include an active region 622 on a frontside of the upper semiconductor die 620. The upper semiconductor die 620 may also include a semiconductor layer 626 (e.g., bulk silicon region) on the active region 622. The frontside of the upper semiconductor die 620 may also include a passivation layer 650 and a plurality of bonding pads 655 in the passivation layer 650. The upper semiconductor die 620 may be connected to the lower package by a plurality of C4 bumps 621 formed on the bonding pads 655, respectively, and connected to the portions of seed layer 212 on the through vias 145, respectively. The thermally conductive underfill layer 50 may be formed on the package structure 100 and around the C4 bumps 621. The thermally conductive underfill layer 50 may completely fill the gap between the upper package 60 and the package structure 100.

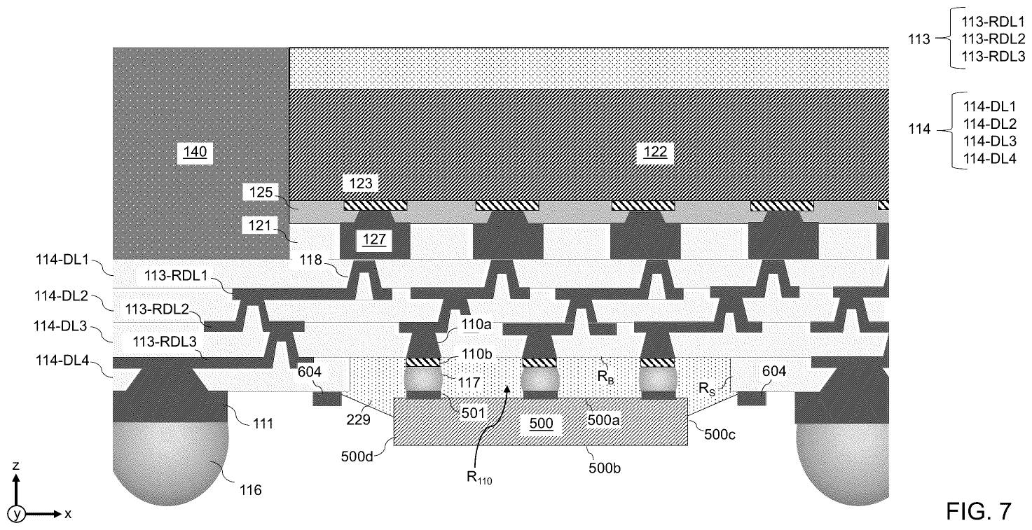

FIG. 7 is a detailed vertical cross-sectional view of a first alternative design of the frontside RDL structure 110 according to one or more embodiments. The first alternative design may be substantially similar to the original design of the frontside RDL structure in FIG. 1C. However, in the first alternative design, the frontside RDL structure 110 does not include the barrier ring 602. In this embodiment, the IPD underfill layer 229 may contact an entirety of the sidewall R_{S} of the recessed portion R₁₁₀. The UBM dam structure 604 located outside the recessed portion R₁₁₀ may contain or impede the spread of the IPD underfill layer 229. The UBM dam structure 604 may therefore be omitted in the first alternative design.

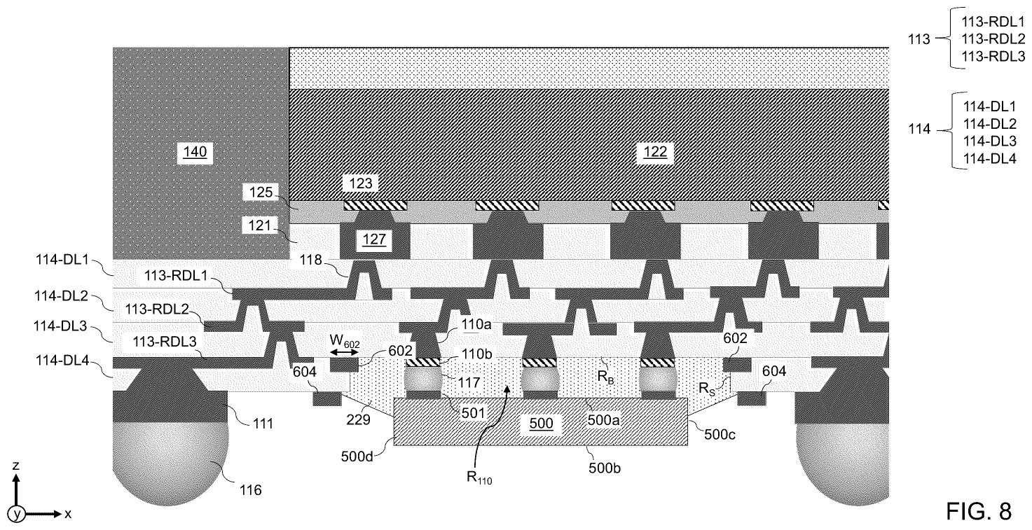

FIG. 8 is a detailed vertical cross-sectional view of a second alternative design of the frontside RDL structure 110 according to one or more embodiments. The second alternative design may be substantially similar to the original design of the frontside RDL structure in FIG. 1C and the first alternative design in FIG. 7. However, in the second alternative design, the distal dielectric layer 114-DL4 (e.g., a polyimide layer) may be formed on at least a portion of the barrier ring 602 in the recessed portion R₁₁₀. That is, the barrier ring 602 may protrude in the x-direction from the sidewall R_{S} of the recessed portion R₁₁₀. In at least one embodiment the distal dielectric layer 114-DL4 may cover at least 50% of the width W₆₀₂ of the barrier ring 602.

Referring to FIGS. 1A-6, a package structure 100 may include a frontside redistribution layer (RDL) structure 110 including a recessed portion R₁₁₀, a lower encapsulation layer 140 on the frontside RDL structure 110 and including a plurality of through vias 145 configured to electrically couple the frontside RDL structure 110 to an upper package, a first semiconductor die 120 on the frontside RDL structure 110 and in the lower encapsulation layer 140, and an integrated passive device (IPD) 500 connected to the frontside RDL structure 110 in the recessed portion R₁₁₀ and electrically coupled to the first semiconductor die 120.

In one embodiment, the IPD 500 may include a zero inductance IPD (ZLIPD). In one embodiment, the frontside RDL structure 110 may include a plurality of dielectric layers 114, the recessed portion R₁₁₀ may be located in a distal dielectric layer 114-DL4 of the plurality of dielectric layers 114, and a depth of the recessed portion R₁₁₀ may be substantially the same as a thickness of the distal dielectric layer 114-DL4. In one embodiment, the plurality of dielectric layers 114 may include an intermediate dielectric layer 114-DL3 adjacent the distal dielectric layer 114-DL4, and the IPD 500 may be mounted on the intermediate dielectric layer 114-DL3. In one embodiment, the frontside RDL structure 110 further may include a plurality of redistribution layers 113 and a plurality of contact vias 110a in the intermediate dielectric layer 114-DL3 and contacting a redistribution layer 113 of the plurality of redistribution layers 113. In one embodiment, the package structure 100 may further include a plurality of bonding pads 110b in the recessed portion R₁₁₀ on the intermediate dielectric layer 114-DL3 and contacting the plurality of contact vias 110a, respectively, and a plurality of solder bumps 117 on the plurality of bonding pads 110b, respectively, and connecting the IPD 500 to the plurality of bonding pads 110b. In one embodiment, the package structure 100 may further include an IPD underfill layer 229 in the recessed portion R₁₁₀ between the IPD 500 and the frontside RDL structure 110, and a barrier ring 602 on a bottom surface SB of the recessed portion R₁₁₀ and configured to contain and/or impede a spread of the IPD underfill layer 229. In one embodiment, the frontside RDL structure 110 may include a board-side surface and the recessed portion R₁₁₀ may be located in the board-side surface. In one embodiment, the package structure 100 may further include an IPD underfill layer 229 that fills the recessed portion R₁₁₀ between the IPD 500 and the frontside RDL structure 110, and an underbump metallization (UBM) dam structure 604 on the board-side surface of the frontside RDL structure 110 and configured to contain and/or impede a spread of the IPD underfill layer 229. In one embodiment, a distance between the board-side surface of the frontside RDL structure 110 and a board-side surface of the IPD 500 may be 90 μm or less. In one embodiment, the package structure 100 may further include a ball grid array (BGA) including a plurality of solder balls 116 on the board-side surface of the frontside RDL structure 110, wherein the IPD 500 may be located adjacent to the plurality of solder balls 116. In one embodiment, a distance between the board-side surface of the frontside RDL structure 110 and an end of the plurality of solder balls 116 may be 120 μm or less. In one embodiment, a width of the recessed portion R₁₁₀ may be at least 1.5 times a width of the IPD 500.

Referring again to FIGS. 1A-6, a method of forming a package structure 100 may include forming a molded portion 115 including a lower encapsulation layer 140, a plurality of through vias 145 in the lower encapsulation layer 140 and a first semiconductor die 120 in the lower encapsulation layer 140, forming a frontside redistribution layer (RDL) structure 110 including a recessed portion R₁₁₀ on the molded portion 115, wherein the plurality of through vias 145 are configured to electrically couple the frontside RDL structure 110 to an upper package, and attaching an integrated passive device (IPD) 500 to the frontside RDL structure 110 in the recessed portion R₁₁₀, wherein the IPD 500 may be electrically coupled to the first semiconductor die 120.

In one embodiment, the method may include forming of the frontside RDL structure 110 which may include depositing a plurality of dielectric layers 114 on the molded portion 115, and etching a distal dielectric layer 114-DL4 of the plurality of dielectric layers 114 to form the recessed portion R₁₁₀ in the distal dielectric layer 114-DL4. The method may further include forming an IPD underfill layer 229 in the recessed portion R₁₁₀ between the IPD 500 and the frontside RDL structure 110, and forming a barrier ring 602 on a bottom surface SB of the recessed portion R₁₁₀, wherein the barrier ring 602 may be configured to contain and/or impede a spread of the IPD underfill layer 229. In one embodiment, the method may further include forming an IPD underfill layer 229 that fills the recessed portion R₁₁₀ between the IPD 500 and the frontside RDL structure 110, and forming an underbump metallization (UBM) dam structure 604 on the board-side surface of the frontside RDL structure 110, wherein the UBM dam structure 604 may be configured to contain and/or impede a spread of the IPD underfill layer 229. In one embodiment, the method may further include forming a plurality of solder balls 116 on a board-side surface of the frontside RDL structure 110, wherein a distance between the board-side surface of the frontside RDL structure 110 and an end of the plurality of solder balls 116 may be 120 μm or less.

Referring again to FIGS. 1A-6, a semiconductor package 550 may include a package substrate 510, a semiconductor device 400, 600 including a package structure 100 on the package substrate 510, the package structure 100 including a frontside redistribution layer (RDL) structure 110 including a recessed portion R₁₁₀, a lower encapsulation layer 140 on the frontside RDL structure 110 and including a plurality of through vias 145 configured to electrically couple the frontside RDL structure 110 to an upper package, a first semiconductor die 120 on the frontside RDL structure 110 and in the lower encapsulation layer 140, and an integrated passive device (IPD) 500 attached to the frontside RDL structure 110 in the recessed portion R₁₁₀ and electrically coupled to the first semiconductor die 120, and a package underfill layer 529 between the package substrate 510 and the semiconductor device 400, 600.

In one embodiment, the semiconductor package 550 may further include an IPD underfill layer 229 in the recessed portion R₁₁₀ between the IPD 500 and the frontside RDL structure 110, wherein the package underfill layer 529 is on the IPD underfill layer, and a spread impeding structure 602, 604 on the frontside RDL structure 110 and configured to contain and/or impede a spread of the IPD underfill layer 229.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a frontside redistribution layer (RDL) structure including a recessed portion;
a lower encapsulation layer on the frontside RDL structure and including a plurality of through vias configured to electrically couple the frontside RDL structure to an upper package;
a first semiconductor die on the frontside RDL structure and in the lower encapsulation layer; and
an integrated passive device (IPD) connected to the frontside RDL structure in the recessed portion and electrically coupled to the first semiconductor die.

2. The package structure of claim 1, wherein the IPD comprises a zero inductance IPD (ZLIPD).

3. The package structure of claim 1, wherein the frontside RDL structure includes a plurality of dielectric layers, the recessed portion is located in a distal dielectric layer of the plurality of dielectric layers, and a depth of the recessed portion substantially equals a thickness of the distal dielectric layer.

4. The package structure of claim 3, wherein the plurality of dielectric layers includes an intermediate dielectric layer adjacent the distal dielectric layer, and the IPD is mounted on the intermediate dielectric layer.

5. The package structure of claim 4, wherein the frontside RDL structure further includes a plurality of redistribution layers and a plurality of contact vias in the intermediate dielectric layer and contacting a redistribution layer of the plurality of redistribution layers.

6. The package structure of claim 5, further comprising:
a plurality of bonding pads in the recessed portion on the intermediate dielectric layer and contacting the plurality of contact vias, respectively; and
a plurality of solder bumps on the plurality of bonding pads, respectively, and connecting the IPD to the plurality of bonding pads.

7. The package structure of claim 1, further comprising:
an IPD underfill layer in the recessed portion between the IPD and the frontside RDL structure; and
a barrier ring on a bottom surface of the recessed portion and configured to contain a spread of the IPD underfill layer.

8. The package structure of claim 1, wherein the frontside RDL structure comprises a board-side surface and the recessed portion is located in the board-side surface.

9. The package structure of claim 8, further comprising:
an IPD underfill layer that fills the recessed portion between the IPD and the frontside RDL structure; and
an underbump metallization (UBM) dam structure on the board-side surface of the frontside RDL structure and configured to contain a spread of the IPD underfill layer.

10. The package structure of claim 8, wherein a distance between the board-side surface of the frontside RDL structure and a board-side surface of the IPD is 90 μm or less.

11. The package structure of claim 8, further comprising:
a ball grid array (BGA) including a plurality of solder balls on the board-side surface of the frontside RDL structure, wherein the IPD is located adjacent to the plurality of solder balls.

12. The package structure of claim 11, wherein a distance between the board-side surface of the frontside RDL structure and an end of the plurality of solder balls is 120 μm or less.

13. The package structure of claim 1, wherein a width of the recessed portion is at least 1.5 times a width of the IPD.

14. A method of forming a package structure, the method comprising:
forming a molded portion including a lower encapsulation layer, a plurality of through vias in the lower encapsulation layer and a first semiconductor die in the lower encapsulation layer;
forming a frontside redistribution layer (RDL) structure including a recessed portion on the molded portion, wherein the plurality of through vias are configured to electrically couple the frontside RDL structure to an upper package; and
attaching an integrated passive device (IPD) to the frontside RDL structure in the recessed portion, wherein the IPD is electrically coupled to the first semiconductor die.

15. The method of claim 14, wherein the forming of the frontside RDL structure comprises:
depositing a plurality of dielectric layers on the molded portion; and
etching a distal dielectric layer of the plurality of dielectric layers to form the recessed portion in the distal dielectric layer.

16. The method of claim 14, further comprising:
forming an IPD underfill layer in the recessed portion between the IPD and the frontside RDL structure; and
forming a barrier ring on a bottom surface of the recessed portion, wherein the barrier ring is configured to contain a spread of the IPD underfill layer.

17. The method of claim 14, further comprising:
forming an IPD underfill layer that fills the recessed portion between the IPD and the frontside RDL structure; and
forming an underbump metallization (UBM) dam structure on a board-side surface of the frontside RDL structure, wherein the UBM dam structure is configured to impede a contain of the IPD underfill layer.

18. The method of claim 14, further comprising:
forming a plurality of solder balls on a board-side surface of the frontside RDL structure, wherein a distance between the board-side surface of the frontside RDL structure and an end of the plurality of solder balls is 120 μm or less.

19. A semiconductor package, comprising:
a package substrate;
a semiconductor device including a package structure on the package substrate, the package structure comprising:
a frontside redistribution layer (RDL) structure including a recessed portion;
a lower encapsulation layer on the frontside RDL structure and including a plurality of through vias configured to electrically couple the frontside RDL structure to an upper package;
a first semiconductor die on the frontside RDL structure and in the lower encapsulation layer; and
an integrated passive device (IPD) attached to the frontside RDL structure in the recessed portion and electrically coupled to the first semiconductor die; and
a package underfill layer between the package substrate and the semiconductor device.

20. The semiconductor package of claim 19, further comprising:
an IPD underfill layer in the recessed portion between the IPD and the frontside RDL structure, wherein the package underfill layer is on the IPD underfill layer; and
a spread impeding structure on the frontside RDL structure and configured to contain a spread of the IPD underfill layer.
